(19) United States
(12) Patent Application Publication
(10) Pub. No.: US 2014/0284682 A1
(43) Pub. Date: Sep. 25, 2014

(54) NONVOLATILE SEMICONDUCTOR STORAGE DEVICE

(71) Applicant: Kabushiki Kaisha Toshiba, Minato-ku (JP)

(72) Inventor: Hideto TAKEKIDA, Nagoya (JP)

(73) Assignee: Kabushiki Kaisha Toshiba, Minato-ku (JP)

(21) Appl. No.: 14/010,686

(22) Filed: Aug. 27, 2013

(30) Foreign Application Priority Data
Mar. 21, 2013 (JP) 2013-058557

(51) Int. Cl. H01L 29/49; H01L 29/423; H01L 29/788

(52) U.S. Cl. CPC H01L 29/4916; H01L 29/788; H01L 29/42328
USPC 257/316

(57) ABSTRACT

A nonvolatile semiconductor storage device is disclosed that includes a p-type semiconductor substrate, a gate insulating film formed above the semiconductor substrate, a memory-cell transistor and a peripheral circuit transistor formed above the gate insulating film. The memory-cell transistor includes a first gate electrode including a stack of a floating gate electrode comprising a p-type first polycrystalline silicon film, an interelectrode insulating film, and a control gate electrode comprising a p-type second polycrystalline silicon film. The peripheral circuit transistor includes a second gate electrode including a stack of a lower electrode comprising an n-type third polycrystalline silicon film; a first insulating film having an opening and being located above the lower electrode, an upper electrode comprising the same material as the second polycrystalline silicon film and contacting the third polycrystalline silicon film through the opening of the first insulating film.

### CROSS-REFERENCE TO RELATED APPLICATION(S)

This application is based upon and claims the benefit of priority from Japanese Patent Application No. 2013-058557, filed on, Mar. 21, 2013 the entire contents of which are incorporated herein by reference.

### FIELD

Embodiments disclosed herein generally relate to a nonvolatile semiconductor storage device.

### BACKGROUND

In nonvolatile semiconductor storage devices such as a NAND flash memory, data storage is typically implemented through a memory-cell transistor employing a stacked gate structure in which a floating gate electrode, an interelectrode insulating film, and a control gate electrode are stacked in the listed sequence. The floating gate electrode and the control gate electrode each typically comprise a polycrystalline silicon film doped with impurities. A NAND flash memory is also typically provided with peripheral circuitry comprising elements such as transistors, resistive elements, and capacitive elements. Because peripheral circuit elements are formed when the memory-cell transistors are formed, the gate electrode of the peripheral circuit transistor and capacitance electrode of the capacitive elements are often formed based on the film structures of the memory-cell transistor. However, when combination of the conductivity types of floating gate electrode and the control gate electrode are determined based on the memory-cell transistor, it may affect the properties of the peripheral circuit transistor or the capacitive element.

### BRIEF DESCRIPTION OF THE DRAWINGS

FIG. 1 is one example of a block diagram schematically illustrating an electrical configuration of a NAND Flash memory device.

FIG. 2 is one example of a planar layout of the memory cell region in part.

FIG. 3 is one example of a simplified cross sectional structure taken along line 3-3 of FIG. 2.

FIG. 4A is one schematic example of a planar layout of peripheral circuit transistor PT in peripheral circuit region PA.

FIG. 4B is one example of a planar layout of capacitive element C.

FIG. 4C is one example of an equivalent circuit representation of capacitive element C indicated in FIG. 4B.

FIGS. 5A to 5E, each illustrates an example of a structure and one phase of the manufacturing process flow of a NAND flash memory device of a first embodiment; where FIG. 5A illustrates one schematic example of a cross-sectional view taken along line 5A-5A of FIG. 2; FIG. 5B illustrates one schematic example of a cross-sectional view taken along line 5B-5B of FIG. 2; FIG. 5C illustrates one schematic example of a cross-sectional view taken along line 5C-5C of FIG. 4A and also is one example of a cross sectional view of an n-channel type transistor Trn; FIG. 5D illustrates one schematic example of a cross-sectional view taken along line 5C-5C of FIG. 4A and also is one example of a cross sectional view of an p-channel type transistor Trp; and FIG. 5E illustrates one schematic example of a cross-sectional view taken along line 5E-5E of FIG. 4B. The same applies to figures suffixed by A, B, C, D, and E in FIGS. 6A to 16E and FIGS. 22A to 22E.

FIGS. 6A to 6E illustrate an example of one phase of the manufacturing process flow of a NAND flash memory device of the first embodiment.

FIGS. 7A to 7E illustrate an example of one phase of the manufacturing process flow of a NAND flash memory device of the first embodiment.

FIGS. 8A to 8E illustrate an example of one phase of the manufacturing process flow of a NAND flash memory device of the first embodiment.

FIGS. 9A to 9E illustrate an example of one phase of the manufacturing process flow of a NAND flash memory device of the first embodiment.

FIGS. 10A to 10E illustrate an example of one phase of the manufacturing process flow of a NAND flash memory device of the first embodiment.

FIGS. 11A to 11E illustrate an example of one phase of the manufacturing process flow of a NAND flash memory device of the first embodiment.

FIGS. 12A to 12E illustrate an example of one phase of the manufacturing process flow of a NAND flash memory device of the first embodiment.

FIGS. 13A to 13E illustrate an example of one phase of the manufacturing process flow of a NAND flash memory device of the first embodiment.

FIGS. 14A to 14E illustrate an example of one phase of the manufacturing process flow of a NAND flash memory device of the first embodiment.

FIGS. 15A to 15E illustrate an example of one phase of the manufacturing process flow of a NAND flash memory device of the first embodiment.

FIGS. 16A to 16E illustrate an example of one phase of the manufacturing process flow of a NAND flash memory device of the first embodiment.

FIGS. 17A to 17E illustrate an example of one phase of the manufacturing process flow of a NAND flash memory device of a second embodiment; where FIG. 17A illustrates one schematic example of a cross-sectional view taken along line 5A-5A of FIG. 2; FIG. 17B illustrates one schematic example of a cross-sectional view taken along line 5B-5B of FIG. 2; FIG. 17C illustrates one schematic example of a cross-sectional view taken along line 17C-17C of FIG. 24 and also is one example of a cross sectional view of an n-channel type transistor Trn; FIG. 17D illustrates one schematic example of a cross-sectional view taken along line 17C-17C of FIG. 24 and also is one example of a cross sectional view of an p-channel type transistor Trp; and FIG. 17E illustrates one schematic example of a cross-sectional view taken along line 5E-5E of FIG. 4B. The same applies to figures suffixed by A, B, C, D, and E in FIGS. 18A to 21E.

FIGS. 18A to 18E illustrate an example of one phase of the manufacturing process flow of a NAND flash memory device of the second embodiment.

FIGS. 19A to 19E illustrate an example of one phase of the manufacturing process flow of a NAND flash memory device of the second embodiment.

FIGS. 20A to 20E illustrate an example of one phase of the manufacturing process flow of a NAND flash memory device of the second embodiment.

FIGS. 21A to 21E illustrate an example of one phase of the manufacturing process flow of a NAND flash memory device of the second embodiment.

FIGS. 22A to 22E each illustrate an example of a structure and one phase of the manufacturing process flow of a NAND flash memory device of a third embodiment.

FIG. 23A is one schematic example of an energy band diagram of a capacitive element representing the embodiments and FIG. 23B is one schematic example of an energy band diagram of a capacitive element representing a comparative example.

FIG. 24 is one example of a planar layout of a peripheral circuit transistor according to a second embodiment.

### DESCRIPTION

In one embodiment, a nonvolatile semiconductor storage device is disclosed.

The nonvolatile semiconductor storage device includes a p-type semiconductor substrate, a gate insulating film formed above the semiconductor substrate, a memory-cell transistor and a peripheral circuit transistor formed above the gate insulating film. The memory-cell transistor includes a first gate electrode including a stack of a floating gate electrode comprising a p-type first polycrystalline silicon film, an interelectrode insulating film, and a control gate electrode comprising a p-type second polycrystalline silicon film. The peripheral circuit transistor includes a second gate electrode including a stack of a lower electrode comprising an n-type third polycrystalline silicon film; a first insulating film having an opening and being located above the lower electrode, an upper electrode comprising the same material as the second polycrystalline silicon film and contacting the third polycrystalline silicon film through the opening of the first insulating film.

### EMBODIMENTS

Embodiments are described hereinafter through a NAND flash memory application with references to the accompanying drawings. The drawings are not drawn to scale and thus, do not reflect the actual measurements of the features such as the correlation of thickness to planar dimensions and the relative thickness of different layers. Further, directional terms such as up, upper, upward, down, lower, downward, left, leftward, right, and rightward are used in a relative context with an assumption that the worked surface, on which circuitry is formed, of the later described semiconductor substrate faces up. Thus, the directional terms do not necessarily correspond to the directions based on gravitational acceleration.

### First Embodiment

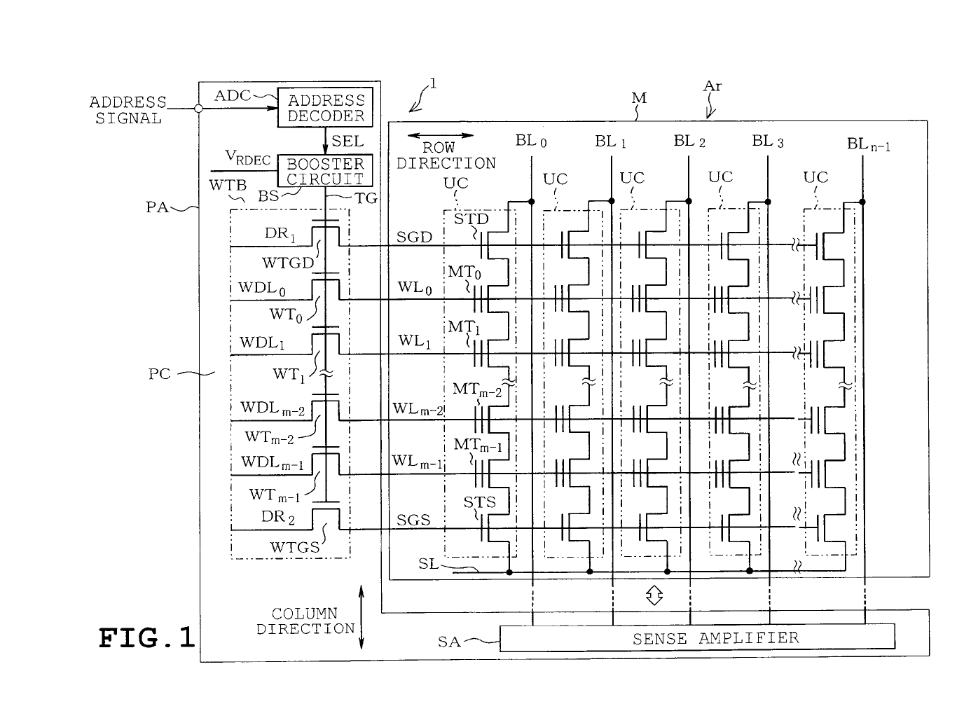

A description is given hereinafter on a first embodiment with reference to FIGS. 1 to 16E and FIG. 23.

FIG. 1 is one schematic example of an electrical configuration of NAND flash memory device 1 represented by a block diagram. As shown in FIG. 1, NAND flash memory device 1 primarily comprises memory cell array Ar, peripheral circuit PC and input/output interface circuitry not shown. Memory cell array Ar is configured by multiplicity of memory cells arranged in a matrix. Peripheral circuit PC is configured to read/program/erase each of the memory cells in memory cell array Ar.

Memory cell array Ar located in memory cell region M includes multiplicity of units of cells referred to as unit memory cell UC. Unit memory cell UC comprises 2^{k}=m number of series connected memory-cell transistors MT₀ to MTₘ₋₁, such as 32 in number, situated between a couple of select transistors STD and STS that are located at Y-direction ends of unit memory cell UC as viewed in FIG. 1. Select transistors STD are connected to bit lines BL₀ to Blₙ₋₁, whereas select transistors STS are connected to source lines SL.

A plurality of unit memory cells UC constitutes a memory-cell block and a plurality of memory-cell blocks, hereinafter also simply referred to as block/blocks, constitutes memory cell array Ar. A single block comprises n number unit memory cells UC, aligned along the left and right direction or the row direction as viewed in FIG. 1. Memory cell array Ar constitutes a plurality of blocks aligned along the up and down direction or the column direction as viewed in FIG. 1. FIG. 1 only shows one block for simplicity.

The gates of select transistors STD are connected to control line SGD. The control gate electrodes of the m^{th} memory-cell transistors MTₘ₋₁ connected to bit lines BL₀ to Blₙ₋₁ are connected to word line WLₘ₋₁. The control gate electrodes of the third memory-cell transistors MT₂ connected to bit lines BL₀ to Blₙ₋₁ are connected to word line WL₂. The control gate electrode of second memory-cell transistors MT₁ connected to bit lines BL₀ to Blₙ₋₁ are connected to word line WL¹. The control gate electrodes of first memory-cell transistors MT₀ connected to bit lines BL₀ to Blₙ₋₁ are connected to word line WL₀. The gates of select transistors STS connected to source lines SL are connected to control line SGS. Control lines SGD, word lines WL₀ to WLₘ₋₁, control lines SGS and source lines SL each intersect with bit lines BL₀ to Blₙ₋₁.

Memory cell region M is surrounded by peripheral circuit region PA and as shown in FIG. 1, peripheral circuit PC is located in peripheral circuit region PA. Peripheral circuit PC includes address decoder ADC, sense amplifier SA, step-up circuit BS provided with a charge pump circuit, and transfer transistor WTB. Address decoder ADC is electrically connected to transfer transistor WTB through step-up circuit BS. Though not shown in FIG. 1, the circuit elements of peripheral circuit PC include capacitive element C.

Address decoder ADC selects a given block based on an incoming address signal provided from an external component. Step-up circuit BS receives drive voltage V_{RDCE} from an external component, and when receiving block selection signal of a given block from address decoder ADC, steps up drive voltage V_{RDCE} and supplies the stepped up voltage, being stepped up to a predetermined level, to transfer transistors WTGD, WTGS, and WT₀ to WTₘ₋₁ by way of transfer gate line TG.

Transfer transistor WTB is a general identification for transfer transistor WTGD associated with select transistor STD, transfer transistor WTGS associated with select transistor STS, and word line transfer transistors WT₀ to WTₘ₋₁ associated with memory-cell transistors MT₀ to MTₘ₋₁. Transfer transistor WTB is given on a block by block basis.

Each of the transfer transistor WTGD is configured such that either of the drain and source is connected to select gate driver line DR1, and the remaining other is connected to control line SGD that controls select transistor STD. Each of transfer transistor WTGS is configured such that either of the drain and source is connected to select gate driver line DR2, and the remaining other is connected to select gate line SGS that controls select transistor STS. Each of word line transfer transistors WT₀ to WTₘ₋₁ is configured such that either of the drain and source is connected to word line drive signal line WDL₀ to WDLₘ₋₁ respectively, and the remaining other is connected to word line word lines WL₀ to WLₘ₋₁ provided in memory cell array Ar located in memory cell region M.

Gate electrodes of select transistors STD of the row-directionally aligned unit memory cells UC are electrically connected by common control line SGD. Similarly, gate electrodes of select transistors STS of the row directionally aligned unit memory cells UC are electrically connected by common control line SGS. As described earlier, the source of each select transistor STS is connected to common source line SL.

Gate electrodes of memory-cell transistors MT₀ to MTₘ₋₁ of the row-directionally aligned unit memory cells UC are each electrically connected by common word line WL₀ to WLₘ₋₁ respectively.

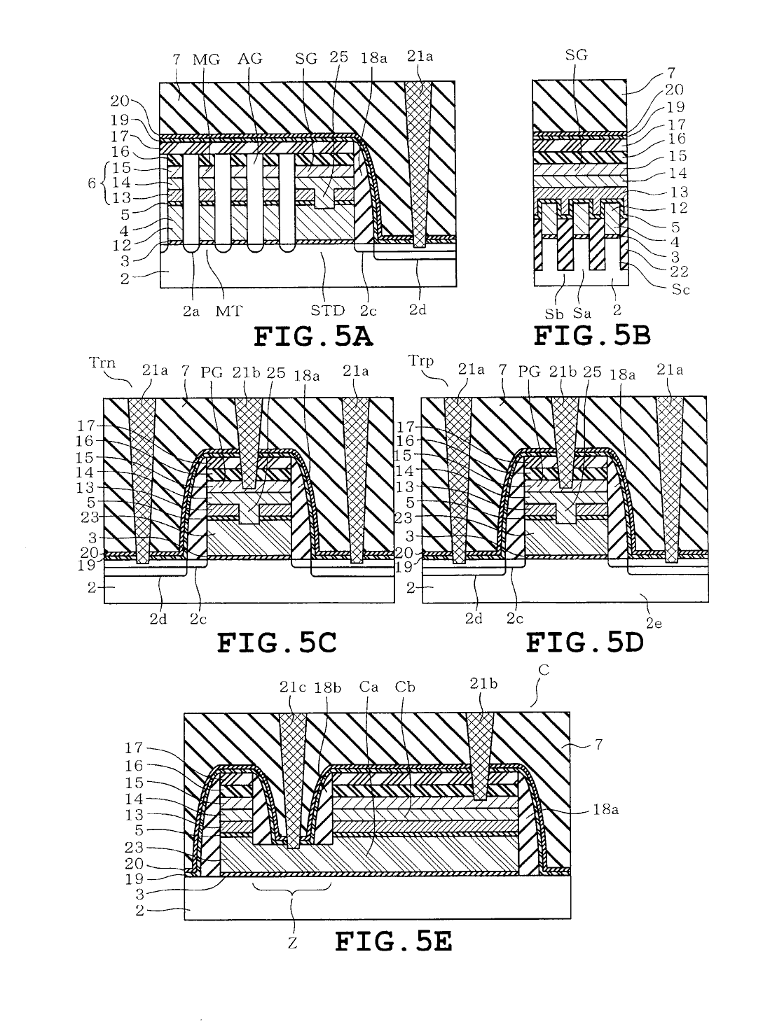

Gate electrodes of transfer transistors WTGD, WTGS, and WT₀ to WTₘ₋₁ are interconnected by common transfer gate line TG, which is turn, connected to an output terminal of step up circuit BS. Sense amplifier SA is connected to bit line BL₀ to Blₙ₋₁ and is further connected to a latch circuit that serves as a temporary storage of data read during a read operation. In FIG. 5A and beyond, peripheral circuit transistors formed in peripheral circuit region PA are represented as transistor Trn in case of an n-channel type transistor and as transistor Trp in case of a p-channel type transistor.

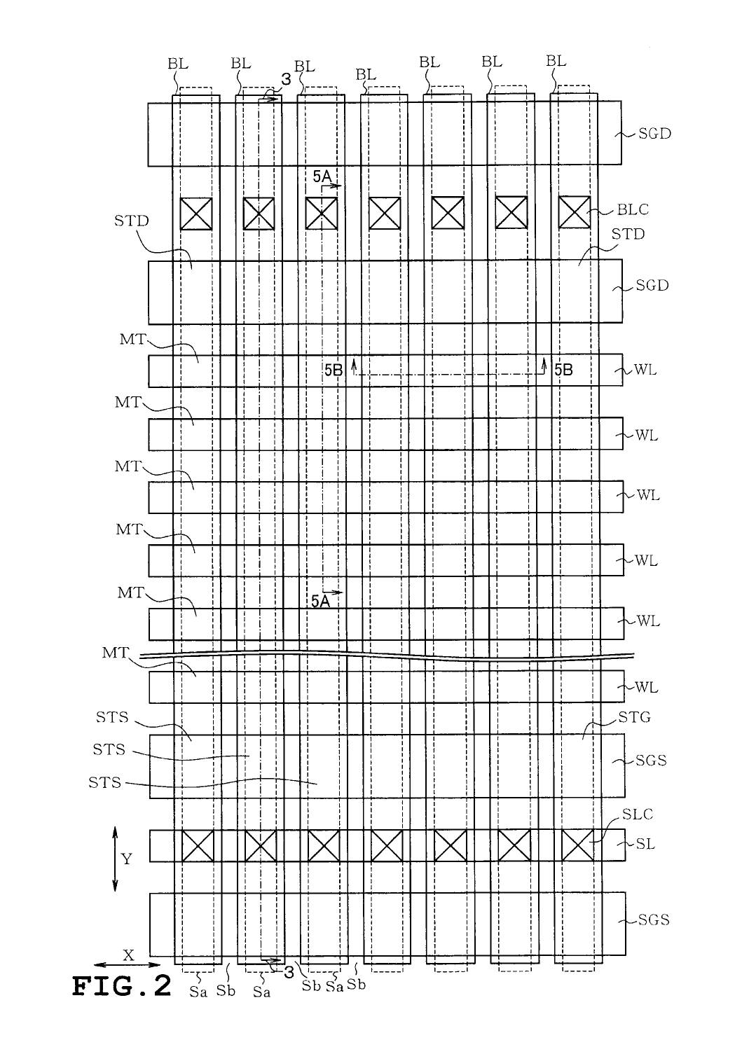

FIG. 2 is one schematic example of a planar layout of the memory cell region M in part. Bit lines BL₀ to BLₙ₋₁, word lines WL₀ to WLₘ₋₁, and memory-cell transistors MT₀ to MTₘ₋₁ are also hereinafter referred to as bit line(s) BL, word line(s) WL, and memory-cell transistor(s) MT for simplicity.

As shown in FIG. 2, source line SL, control line SGS, and control line SGD each run in the X direction and are spaced from one another in the Y direction. The Y direction is the up and down direction which is indicated as the column direction in FIG. 1, whereas the X direction is the left and right direction which is indicated as the row direction in FIG. 1. Bit lines BL each run in the Y direction and are spaced from one another in the X direction by a predetermined distance.

In memory cell region M of silicon substrate 2 below bit lines BL, element isolation regions Sb run in the Y direction. The isolation scheme being employed is an STI (shallow trench isolation) scheme in which trenches are filled with an insulating film. Element isolation regions Sb are spaced from one another in the X direction as viewed in FIG. 2 by a predetermined distance. Thus, element isolation regions Sb isolate element regions Sa, formed in a surface layer of semiconductor substrate 2 along the Y direction, in the X direction. In other words, element isolation region Sb is located between element isolation regions Sa, meaning that silicon substrate 2, is delineated into a plurality of element regions Sa by element isolation region Sb. In the embodiments disclosed herein, silicon substrate 2 is employed as one example of a semiconductor substrate.

Still referring to FIG. 2, multiplicity of word lines WL, spaced from one another in the Y direction by a predetermined distance, extend in the X direction which is the direction orthogonal to the Y direction in which element region Sa extend. Above element region Sa located at the intersection with word line WL, memory-cell transistor MT is formed. Similarly, above element region Sa located at the intersection with control lines SGS and SGD, select transistors STS and STD are formed.

The Y-directionally adjacent memory-cell transistors MT constitute a part of a NAND string also referred to as a memory-cell string. Select transistors STS and STD are typically provided on the Y-directional ends of the NAND string such that the Y-directionally adjacent memory-cell transistors MT are interposed between the pair of select transistors STS and STD.

As described earlier, a plurality of select transistors STS connected to source line SL is aligned in the X direction and gate electrodes of select transistors STS are electrically interconnected by control line SGS. The gate electrode of select transistor STS is formed above element region Sa intersecting with control line SGS. Source contact SLC is provided at the intersection of source line SL and bit line BL. A plurality of select transistors STD is aligned in the X direction and gate electrodes of select transistors STD are electrically interconnected by control line SGD. The gate electrode of select transistor STD is formed above element region Sa intersecting with control line SGD. Bit line contact BLC is provided in element region Sa located between the adjacent select transistors STD.

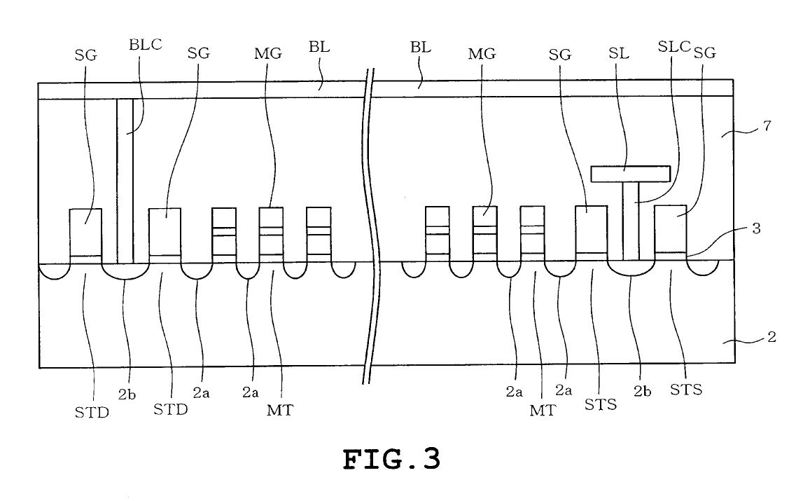

FIG. 3 is one example of a simplified view of a cross sectional structure taken along line 3-3 of FIG. 2. As shown in FIG. 3, gate electrodes MG of memory-cell transistors MT and gate electrodes SG of select transistors STS and STD are formed above the upper surface of silicon substrate 2 via gate insulating film 3. Memory-cell transistor MT includes gate electrode MG formed above gate insulating film 3, and source/drain regions 2a. A plurality of memory-cell transistors MT is formed adjacent to one another in the left and right direction as viewed in FIG. 3. A pair of select transistors STS are provided on one end of the string of memory-cell transistors MT and a pair of select transistors STD are provided on the other end of the string of memory-cell transistors MT.

Gate electrode MG of memory-cell transistors MT is formed above gate insulating film 3 and comprises floating gate electrode 4 for storing charge, interelectrode insulating film 5, and control gate electrode 6.

In the surface layer of silicon substrate 2 located between gate electrodes MG and between gate electrodes SG and MG, source/drain regions 2a are formed. In the surface layer of silicon substrate 2 located between gate electrodes SG, drain region 2b is formed which is heavily doped with impurities.

Though only schematically shown in FIG. 3, gate electrodes SG of select transistors STD and STS are substantially identical in structure to gate electrode MG of memory-cell transistor MT and thus, are configured by a stack of films corresponding to floating gate electrode 4, interelectrode insulating film 5, and control gate electrode 6 provided above gate insulating film 3. Select gate electrode SG has opening 25 shown in FIGS. 5C and 5D formed through the central portion of interelectrode insulating film 5 to render the film corresponding to floating gate electrode 4 and the film corresponding to control gate electrode 6 electrically conductive to obtain a gate electrode of a normal transistor that does not possess a floating gate electrode.

Above gate electrodes MG and SG of the foregoing structure, interlayer insulating film 7 is formed. Though not shown in detail in FIG. 3, an air gap structure shown in FIG. 5A may be employed in which the gaps between gate electrodes MG and between gate electrodes MG and SG may be left unfilled by interlayer insulating film 7 to provide insulation by unfilled gaps generally referred to and shown as air gap AG.

Source contact SLC is configured to extend through interlayer insulating film 7 to establish contact with source/drain region 2b of silicon substrate 2 located between gate electrodes SG of select transistors STS. Bit line contact BLC is configured to extend through interlayer insulating film 7 to establish contact with source/drain region 2b of silicon substrate 2 located between gate electrodes SG of select transistors STD. Interlayer insulating film 7 is provided with source line SL and bit line BL which are connected with source line contact SLC and bit line contact BLC, respectively. Source line SL and bit line BL extend in the direction orthogonal to one another. The basic structures of NAND flash memory device to which the first embodiment is directed is as described above.

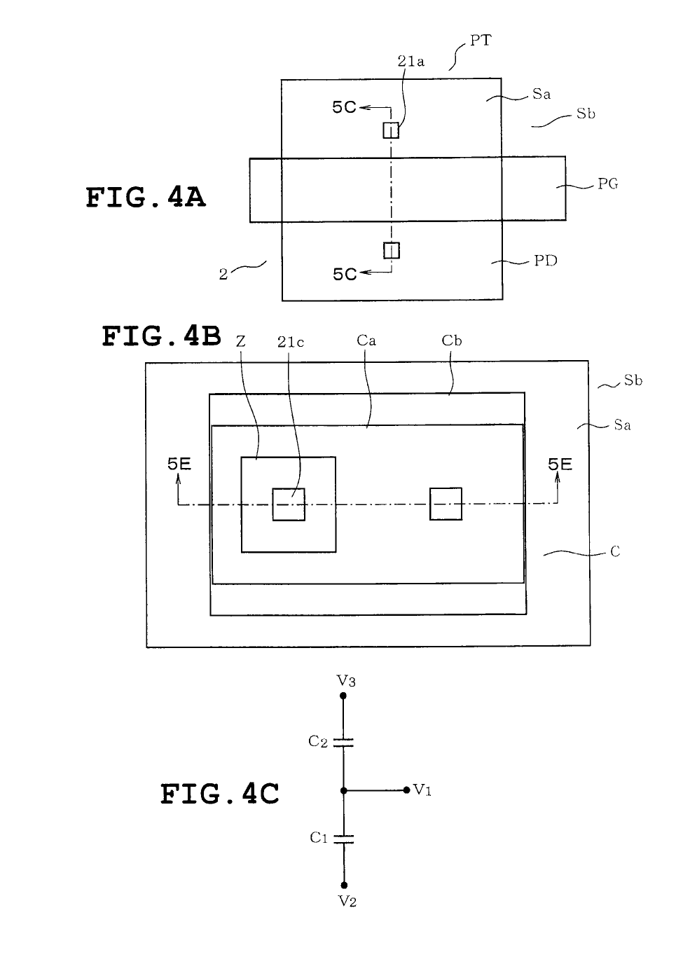

The structures of peripheral circuit elements of the first embodiment will be described in detail with reference to FIGS. 4A to 16E.

FIG. 4A is one schematic example of a planar layout of peripheral circuit transistor PT. FIG. 4B is one schematic example of a planar layout of capacitive element C. FIG. 4C is one example of an equivalent circuit representation of capacitive element C indicated in FIG. 4B. The structures illustrated in FIGS. 4A to 4C will be later described.

FIG. 5A is one schematic example of a cross sectional view taken along line 5A-5A of FIG. 2 and illustrates the cross sectional structure spanning from memory-cell transistors MT, select transistor STD, and bit line contact BLC. FIG. 5B is one schematic example of a cross sectional view taken along line 5B-5B of FIG. 2 and illustrates the cross sectional structure taken along the word line of the memory cells. FIGS. 5C and 5D are schematic examples of cross sectional views taken along line 5C-5C of FIG. 4A and illustrates the cross sectional structure taken along the length direction of the gate of peripheral circuit transistor PT.

FIG. 5C is one example of a cross sectional structure of an n-channel type transistor Trn. FIG. 5D is one example of a cross sectional structure of an p-channel type transistor Trp. FIG. 5E is one example of a cross sectional structure taken along line 5E-5E of FIG. 4B and also is also one example of a cross sectional structure of capacitive element C.

Referring to FIGS. 5A and 5B, the structures from memory-cell transistors MT of the memory cell region M to select transistor STD in the bit line side and its contact region will be described in detail. The corresponding structures for select transistor STS in the source line side is substantially identical to those of select transistor STD in the bit line side described hereinafter.

In FIG. 5A, silicon substrate 2 corresponds to element region Sa. Gate electrode MG of memory-cell transistor MT and gate electrode SG of select transistor STD are formed above silicon substrate 2. In the embodiments disclosed herein silicon substrate 2 comprises a p-type silicon substrate. Gate electrode MG comprises floating gate electrode 4, interelectrode insulating film 5, and control gate electrode 6 stacked in the listed sequence above gate insulating film 3.

In the first embodiment, gate insulating film 3 comprises a silicon oxide film and floating gate electrode 4 comprises first silicon polycrystalline silicon film 12 doped with impurities. One example of impurities doped in first polycrystalline silicon film 12 is boron of a p-conducive type. In the following description, when silicon or polycrystalline silicon is referred to as being a p type or an n type, it is an indication that their conductivity types are p type or n type.

Interelectrode insulating film 5 may take an ONO structure comprising a stack of oxide/nitride/oxide films, which may be provided with additional bottom and top nitrides to take a NONON structure, or may also comprise a high dielectric constant insulating film. Control gate electrode 6 comprises a stack of second polycrystalline silicon film 13 and third polycrystalline silicon film 14 doped with impurities and metal film 15 comprising metal such as tungsten. The impurity doped into second polycrystalline silicon film 13 and third polycrystalline silicon film 14 is boron and thus, the foregoing films are p-type films. Floating gate electrode 4 and control gate electrode 6 are isolated from one another by interelectrode insulating film 5.

Memory-cell transistor MT comprises gate electrode MG and source/drain region 2a formed in silicon substrate 2 located on both sides of gate electrode MG. A plurality of memory-cell transistors MT is formed adjacent to one another so as to share their source/drain regions 2a. Select transistor STD is provided on one end of the string of such memory-cell transistors MT.

Gate electrode SG is substantially identical to gate electrode MG in film structure. Gate electrode SG comprises first polycrystalline silicon film 12, interelectrode insulating film 5, second polycrystalline silicon film 13, third polycrystalline silicon film 14, and metal film 15 stacked in the listed sequence above gate insulating film 3. First polycrystalline silicon film 12 corresponds to floating gate electrode 4 of gate electrode MG and will be hereinafter referred to as a lower electrode film. Second polycrystalline silicon film 13, third polycrystalline silicon film 14, and metal film 15 correspond to control gate electrode 6 of gate electrode MG and will be hereinafter referred to as an upper electrode film.

First polycrystalline silicon film 12, second polycrystalline silicon film 13, and third polycrystalline silicon film 14 are p-type films since they are doped with impurities such as boron. The upper electrode film and the lower electrode film are physically connected through opening 25 of interelectrode film 5 and thus, are electrically conductive. Select transistor STD thus, functions a normal transistor. Silicon nitride film 16 is further formed above metal film 15.

In the surface layer of silicon substrate 2 located between gate electrodes MG and between gate electrodes SG and MG, source/drain region 2a is formed. Source/drain region 2a is doped with impurities such as phosphorous. In the surface layer of silicon substrate 2 located between gate electrodes SG, lightly-doped source/drain region 2c taking an LDD (lightly doped drain) structure is formed which serves as a drain region. Source/drain region 2a and lightly-doped source/drain region 2c can be formed by doping impurities into the surface layer of silicon substrate 2. Further, in the surface layer of silicon substrate 2 located adjacent to spacer 18a formed along the sidewall of gate electrode SG, heavily-doped source/drain region 2d is formed which is heavily doped with impurities. Lightly-doped source/drain region 2c and heavily-doped source/drain region 2d make up the LDD structure.

Between gate electrodes MG and between gate electrodes SG and MG, air gap AG is provided. First insulating film 17 is formed across the top of gate electrodes MG, gate electrode SG, and air gap AG so as to serve as a lid to close air gap AG. First insulating film 17 may comprises a silicon oxide film. Spacer 18a is formed along the sidewall of gate electrode SG which does not constitute air gap AG. Spacer 18a may comprise a silicon oxide film.

First insulating film 17 is blanketed by second insulating film 19 and third insulating film 20. Further above third insulating film 20, interlayer insulating film 7 is formed so as to fill the recess between gate electrodes SG and to bury gate electrodes MG and SG. Contact plug 21a extending in the up and down direction penetrates through interlayer insulating film 7 and further through third insulating film 20 and second insulating film 19 to reach silicon substrate 2 located in the region adjacent gate electrode SG.

FIG. 5B indicates a cross section orthogonal to FIG. 5A. As shown in FIG. 5B, element region Sa is isolated in the left and right direction or the X direction as viewed in FIG. 2 by element isolation region Sb. Gate insulating film 3 is formed above element region Sa and floating gate electrode 4 is formed above gate insulating film 3. Floating gate electrode 4 comprises p-type first polycrystalline silicon film 12 doped with boron impurity.

Element isolation region Sb is filled with element isolation insulating film 22 and the upper surface of element isolation insulating film 22 is located at approximately mid height of floating gate electrode 4. The upper surfaces of floating gate electrode 4 and element isolation film 22 are covered with interelectrode insulating film 5. Above interelectrode insulating film 5, control gate electrode 6 is formed which comprises second polycrystalline silicon film 13, third polycrystalline silicon film 14, and metal film 15. Silicon nitride film 16 is further formed above metal film 15.

As described earlier, memory-cell transistor MT includes floating gate electrode 4 comprising p-type polycrystalline silicon formed above p-type silicon substrate 2 via gate insulating film 3 and n-type source/drain region 2a doped with impurities. Thus, memory-cell transistor MT is configured as a so called p gate-n channel type transistor and therefore is an n-channel type and buried-channel type MISFET.

Select transistor STD includes a lower electrode film comprising p-type polycrystalline silicon formed above p-type silicon substrate 2 via gate insulating film 3 and n-type source/drain regions 2c and 2d doped with impurities. Thus, select transistor STD is configured as a so called p gate-n channel type transistor and therefore is an n-channel type and buried-channel type MISFET.

Referring now to FIGS. 4A, 5C, and 5D, a description will be given on the structure of peripheral circuit transistor PT.

FIG. 4A is one example of a plan view for describing the planar layout of peripheral circuit transistor PT and illustrates the features that are common to n-channel type transistor Trn and p-channel type transistor Trp illustrated in FIGS. 5C and 5D which will be referenced later. Because the planar layouts of an n-channel type transistor and a p-channel type transistor are substantially identical, they are represented by the planar layout illustrated in FIG. 4A. Referring to FIG. 4A, element isolation region Sb is formed in silicon substrate 2 so as to leave a rectangular element region Sa. Element region Sa has isolated gate electrode PG extending across it. Source/drain region PD formed by doping and diffusing impurities into silicon substrate 2 is located on both sides of gate electrode PG.

Referring now to FIGS. 5C and 5D, a description will be given on the cross sectional structure of peripheral circuit transistor PT. FIG. 5C illustrates n-channel type transistor Trn, whereas FIG. 5D illustrates p-channel type transistor Trp.

As shown in FIGS. 5C and 5D, gate insulating film 3 is formed above the upper surface of silicon substrate 2. The thickness of gate insulating film 3 varies depending upon how voltage tolerance is designed in each transistor. For example, a thick gate insulating film 3 is used when the transistor is required to tolerate high level of voltage. Gate electrode PG is provided above gate insulating film 3.

Gate electrode PG comprises a lower electrode film comprising a fourth polycrystalline silicon film 23, interelectrode insulating film 5, and an upper electrode film comprising second polycrystalline silicon film 13, third polycrystalline silicon film 14, and metal film 15. Silicon nitride film 16 is formed above metal film 15. First insulating film 17 is further formed above silicon nitride film 16.

In gate electrode PG, opening 25 is formed through the central portion of interelectrode insulating film 5 through which the lower electrode film and the upper electrode film are rendered electrically conductive. Fourth polycrystalline silicon film 23 is an n-type polycrystalline silicon doped with impurities such as phosphorous or arsenic. Second polycrystalline silicon film 13 and third polycrystalline silicon film 14 are identical to those earlier described with reference to FIGS. 5A and 5B, and are p-type polycrystalline silicon doped with impurities such as boron.

Spacer 18a is formed along both sidewalls of gate electrode PG. Second insulating film 19 and third insulating film 20 are formed so as to cover the upper surface of gate electrode PG, the surface of spacer 18a provided on the sidewalls, and gate insulating film 3 above the surface of silicon substrate 2 located on both sides of gate electrode PG. In silicon substrate 2 located on both sides of gate electrode PG, lightly-doped source/drain region 2c and heavily-doped source/drain region 2d are provided to form an LDD structure.

Interlayer insulating film 7 is blanketed above third insulating film 20. Contact plug 21a extending in the up and down direction penetrates through interlayer insulating film 7 and further through third insulating film 20 and second insulating film 19 to reach heavily-doped source/drain region 2d. Contact plug 21b extending in the up and down direction penetrates through interlayer insulating film 7, third insulating film 20, second insulating film 19, first insulating film 17, and silicon nitride film 16 to reach metal film 15.

In the n-channel type transistor Trn shown in FIG. 5C, impurities such as phosphorous is doped in lightly-doped source/drain region 2c and impurities such as arsenic is doped in heavily-doped source/drain region 2d to form an n-type impurity diffusion region.

Because silicon substrate 2 is a p-type, n-channel type transistor Trn may be formed above p-type silicon substrate 2. Further, a p-well region may be provided in the p-type silicon substrate 2 and an n-channel type transistor Trn may be formed in the p-well region.

In the p-channel type transistor Trp shown in FIG. 5D, on the other hand, boron varying in concentration is doped in lightly-doped source/drain region 2c and heavily-doped source/drain region 2d to form a p-type impurity diffusion region. Further, n-well region 2e is formed in silicon substrate 2 and p-channel type transistor Trp is formed in n-well region 2e.

The above described n-channel type transistor Trn is formed above p-type silicon substrate 2 or above the p-well region and the gate electrode opposing silicon substrate 2 is the n-type fourth polycrystalline silicon film 23. Thus, n-channel type transistor Trn, being configured as an n gate-n channel type transistor, is therefore a surface-channel type MISFET. The above described p-channel type transistor Trp, on the other hand, is formed above the n-well region 2e formed in silicon substrate 2 and the gate electrode opposing silicon substrate 2 is the n-type fourth polycrystalline silicon film 23. Thus, p-channel type transistor Trp, being configured as an n gate-p channel type transistor, is therefore a buried-channel type MISFET.

P-N junction is formed where n-type fourth polycrystalline silicon film 23 contacts p-type second polycrystalline silicon film 13 and third polycrystalline silicon film 14. When positive voltage is applied to second and third polycrystalline silicon films 12 and 14, the P-N junction is forwardly biased to allow carrier transport to the n-type fourth polycrystalline silicon film 23. Fourth polycrystalline silicon film 23, second polycrystalline silicon film 13 and third polycrystalline silicon film 14 are heavily doped with impurities. The dopant concentration may range approximately from 1×10²⁰ to 1×10²¹ atms/cm³. As mentioned earlier, P-N junction is formed where n-type polycrystalline silicon film 23 contacts p-type second polycrystalline silicon film 13 and third polycrystalline silicon film 14. The P-N junction occurs in highly-concentrated n-type/p-type regions and thus, behaves like a tunnel diode. As a result, carrier transport occurs by tunneling even when reverse biased voltage is applied to the P-N junction. According to such configuration, regardless of which voltage, forward or reverse, is applied to the P-N junction from contact plug 21b through metal film 15, second polycrystalline silicon film 13 and third polycrystalline silicon film 14, fourth polycrystalline silicon film 23 becomes conductive and therefore allows the voltage applied to fourth polycrystalline silicon film 23 to be controllable.

Next, a description will be given on the structure of capacitive element C with reference to FIGS. 4B, 4C, and 5E. FIG. 4B is one schematic example of a planar layout of capacitive element C formed in peripheral circuit region. Capacitive element C is formed in element region Sa. Above element region Sa, fourth polycrystalline silicon film 23 is formed via gate insulating film 3. Fourth polycrystalline silicon film 23 serves as first conductor Ca of capacitive element C. Above the upper surface of first conductor Ca, second conductor Cb is formed being similar in structure to control gate electrode 6 which is a component of the gate structure of memory-cell transistor MT. Interelectrode insulating film 5 is formed between first conductor Ca and second conductor Cb.

There is a region in first conductor Ca in which neither second conductor Cb nor interelectrode insulating film 5 is formed. This region is hereinafter referred to as region Z. Contact plug 21c is formed in the Z region so as to be electrically connected to first conductor Ca. Contact plug 21b is further formed so as to be electrically connected to the second conductor Cb. Region Z need not be rectangular but also may be circular or oval. Region Z may further be shaped in a straight, linear shape so as to divide second conductor Cb in to 2 sections.

FIG. 4C illustrates one example of an equivalent circuit of capacitive element C formed as described above. Capacitive element C comprises first capacitive element C1 and second capacitive element C2 connected in series. First capacitive element C1 comprises silicon substrate 2 located in element region Sa, first conductor Ca, and gate insulating film 3 provided therebetween. Second capacitive element C2 is a parallel-plate type formed of first conductor Ca, second conductor Cb, and interelectrode insulating film 5 provided therebetween.

Referring to FIG. 5E, a description will be given on the cross sectional structure of capacitive element C. FIG. 5E illustrates one example of a cross sectional structure taken along line 5E-5E of FIG. 4B. Silicon substrate 2 corresponds to element region Sa and is insulated and isolated by element isolation region Sb surrounding it. Gate insulating film 3 is provided above the upper surface of silicon substrate 2. Gate insulating film 3 may comprise a silicon oxide film. Above gate insulating film 3, fourth polycrystalline silicon film 23 is provided which serves as first conductor Ca of capacitive element C. Fourth polycrystalline silicon film 23 is an n-type polycrystalline silicon which is doped with impurities such as phosphorous or arsenic. Interelectrode insulating film 5 is provided above fourth polycrystalline silicon film 23. Above interelectrode insulating film 5, second polycrystalline silicon film 13, third polycrystalline silicon film 14, and metal film 15 are provided that serve as second conductor Cb of capacitive element C. This film structure corresponds to the film structure of control gate electrode 6 in memory-cell transistor MT.

First conductor Ca and second conductor Cb are insulated by interelectrode insulating film 5. Second polycrystalline silicon film 13 and third polycrystalline silicon film 14 are p-type polycrystalline silicon doped with impurities such as boron. Silicon nitride film 16 is provided above metal film 15 and first insulating film 17 is further provided above silicon nitride film 16.

Fourth polycrystalline silicon film 23 has region Z. Along the sidewalls of the stack of second conductor Cb, silicon nitride film 16, and first insulating film 17 located at the edges of region Z, spacer 18b is formed. Along the sidewall of the stack of first conductor Ca, interelectorde insulating film 5, second conductor Cb, silicon nitride film 16, and first insulating film 17 located on the ends of capacitive element C, spacer 18a is formed. Spacers 18a and 18b may comprise a silicon oxide film.

In the upper portion of the above described structure, second insulating film 19, third insulating film 20, and interlayer insulating film 7 are provided. Contact plug 21c is provided in region Z of first conductor Ca which extends in the up and down direction through interlayer insulating film 7, third insulating film 20, and second insulating film 19 and further extending into the surface layer of fourth polycrystalline silicon film 23. Contact plug 21b is provided above second conductor Cb which extends in the up and down direction through interlayer insulating film 7, third insulating film 20, second insulating film 19, first insulating film 17, and silicon nitride film 16 and further extending into the surface layer of metal film 15. Capacitive element C including first capacitive element C1 comprising silicon substrate 2 and first conductor Ca and second capacitive element C2 comprising first conductor Ca and second conductor Cb are structured in the above described manner.

FIG. 4C is one example of an equivalent circuit representation of capacitive element C. In FIG. 4C, capacitive element C is provided with first capacitive element C1 and second capacitive element C2 that are series connected between terminal V2 and terminal V3. Terminal V1 connecting to the electrode between first capacitive element C1 and second capacitive element C2 correspond to contact plug 21c describe earlier. Contact plug 21c is connected to first conductor Ca and gives a common predetermined potential to first conductor Ca of first capacitive element C1 and second capacitive element C2.

Terminal V2 of first capacitive element C1 corresponds to silicon substrate 2, or more specifically, element region Sa. Silicon substrate 2 opposes first conductor Ca via the aforementioned gate insulating film 3 and is a component of first capacitive element C1.

Terminal V3 of second capacitive element C2 corresponds to contact plug 21b. Contact plug 21b is connected to the aforementioned second conductor Cb. Second conductor Cb opposes the first conductor Ca via interelectrode insulating film 5 and is a component of second capacitive element C2.

To summarize, capacitive element C comprises first capacitive element C1 and second capacitive element C2 which share first conductor Ca and which are located between element region Sa and second conductor Cb. First capacitive element C1 and second capacitive element C2 are series connected between terminals V2 and V3 and taken together form capacitive element C.

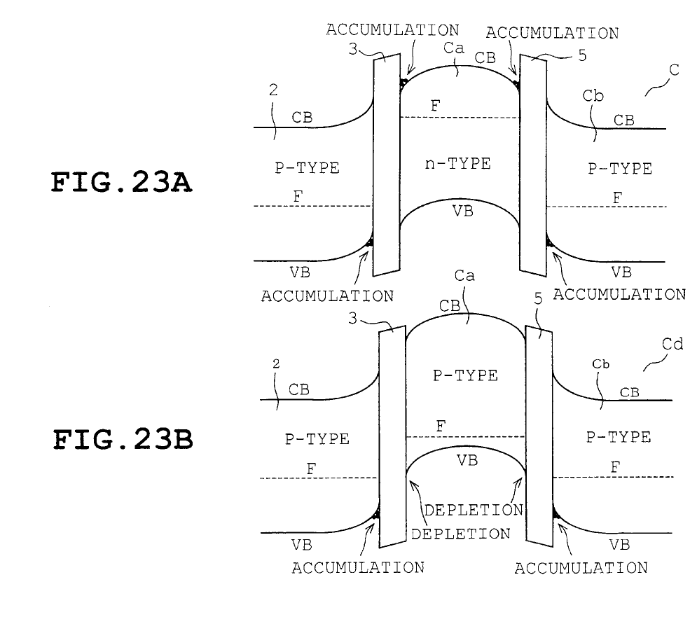

The working of capacitive element C is described hereinafter. As described earlier, capacitive element C is formed of first conductor Ca comprising p-type silicon substrate 2 and n-type fourth polycrystalline silicon film 23, and second conductor Cb comprising p-type second polycrystalline silicon film 13, third polycrystalline silicon film 14, and metal film 15. FIG. 23A is one example of an energy band diagram of silicon substrate 2, gate insulating film 3, fourth polycrystalline silicon film 23 of first conductor Ca, interelectrode insulating film 5, and second polycrystalline silicon film 13 and third polycrystalline silicon film 14 of second conductor Cb when a negative voltage is applied to silicon substrate 2 and second conductor Cb.

FIG. 23A indicates, from left to right, silicon substrate, gate insulating film 3, first conductor Ca (fourth polycrystalline silicon film 23), interelectrode insulating film 5, second conductor Cb (second polycrystalline silicon film 13 and third polycrystalline silicon film 14). The vertical direction represents electron energy. In each of the bands of silicon substrate 2, first conductor Ca, and second conductor Cb, the upper solid line represents the bottom of the conductive band and the lower solid line VB represents the top of the valence bond. The region between solid lines CB and VB represents the band gap, and wave line F represents the Fermi level in the band gap.

When a negative voltage is applied to first conductor Ca in FIG. 23A, the energy of first conductor Ca is increased. This causes a bend in the band of gate insulating film 3 and an upward bend of the band of silicon substrate 2 near the interface with gate insulating film 3 as viewed in FIG. 23A. Similarly, the band of interelectrode insulating film 5 and the band of second polycrystalline silicon film 13 and third polycrystalline silicon film 14 near the interface with interelectrode insulating film 5 is bent upward. Further, the band of first conductor Ca near the interface with gate insulating film 3 and the band of second conductor Cb near the interface with interelectrode insulating film 5 is bent downward.

As described above, silicon substrate is a p type, fourth polycrystalline silicon film 23 of first conductor Ca is an n type, and second polycrystalline silicon film 13 and third polycrystalline silicon film 14 contacting interelectrode insulating film 5 of second conductor Cb are p types. Thus, silicon substrate 2 near the interface with gate insulating film 3, first conductor Ca near the interface with gate insulating film 3 and near the interface with interelectrode insulating film 5, and second conductor Cb near the interface with interelectrode insulating film 5 are placed in an accumulated state. This means that holes are accumulated in silicon substrate 2 near the interface with gate insulating film 3, electrons are accumulated in first conductor Ca near the interface with gate insulating film 3 and the interface with interelectrode insulating film 5, and holes are accumulated in second conductive layer Cb near the interface with interelectrode insulating film 5.

Thus, the capacitance of capacitive element C is the sum of the capacitance of first capacitive element C1 in which gate insulating film 3 is located between silicon substrate 2 and first conductor Ca and the capacitance of second capacitive element C2 in which interelectrode insulating film 5 is located between first conductor Ca and second conductor Cb.

FIG. 23B is one example of a band diagram of capacitive element Cd which is a comparative example for comparison with capacitive element C described above. In the comparative example, capacitive element Cd including silicon substrate 2, first conductor Ca comprising polycrystalline silicon, and second conductor Cb comprising polycrystalline silicon are all p type.

This structure simulates a case in which polycrystalline silicon of first conductor Ca and polycrystalline silicon of second conductor Cb are formed when polycrystalline silicon of floating gate electrode 4 and polycrystalline silicon of control gate electrode 6 of memory-cell transistor MT are formed, meaning that polycrystalline silicon film of first conductor Ca, second conductor Cb, and floating gate electrode 4 are formed in the same manufacturing step. Floating gate electrode 4 of memory-cell transistor MT of the first embodiment comprises p-type first polycrystalline silicon film 12 and second conductor Cb comprises p-type second polycrystalline silicon film 13 and third polycrystalline silicon film 14. Thus, the comparative example simulates first conductor Ca comprising p-type first polycrystalline silicon film 12 and second conductor Cb comprising p-type second polycrystalline silicon film 13 and third polycrystalline silicon film 14.

When negative voltage is applied to first conductor Ca of capacitive element Cd in such structure, silicon substrate 2 near the interface with gate insulating film 3, second conductor Cb (second polycrystalline silicon film 13 and third polycrystalline silicon film 14) near the interface with interelectrode insulating film 5 are placed in an accumulated state. On the other hand, because first polycrystalline silicon film 12 forming first conductor Ca is a p type, first conductor Ca near the interface with gate insulating film 3 and near the interface with interelectrode insulating film 5 are placed in a depleted state. This means that a depleted layer is formed in first conductor Ca near the interface with gate insulating film 3 and near the interface with interelectrode insulating film 5. The depleted layer behaves as an electrically isolated region. Thus, the capacitive insulation film of capacitive element Cd is configured by the depleted layer of gate insulating film 3 and the depleted layer of interelectrode insulating film 5. The capacitance of capacitive element Cd is reduced as compared to a structure in which a depleted layer does not exist.

As described above, the capacitance of capacitive element C in which a depleted layer does not exist is greater than the capacitance of capacitive element Cd in which a depleted layer does exist. Accordingly, the first embodiment obtains a capacitive element having large capacitance per unit area. This contributes in reducing the chip area and consequently the cost of a nonvolatile semiconductor storage device.

Next, a description will be given on the process flow for manufacturing the nonvolatile semiconductor storage device of the first embodiment with reference to FIGS. 5A to 16E.

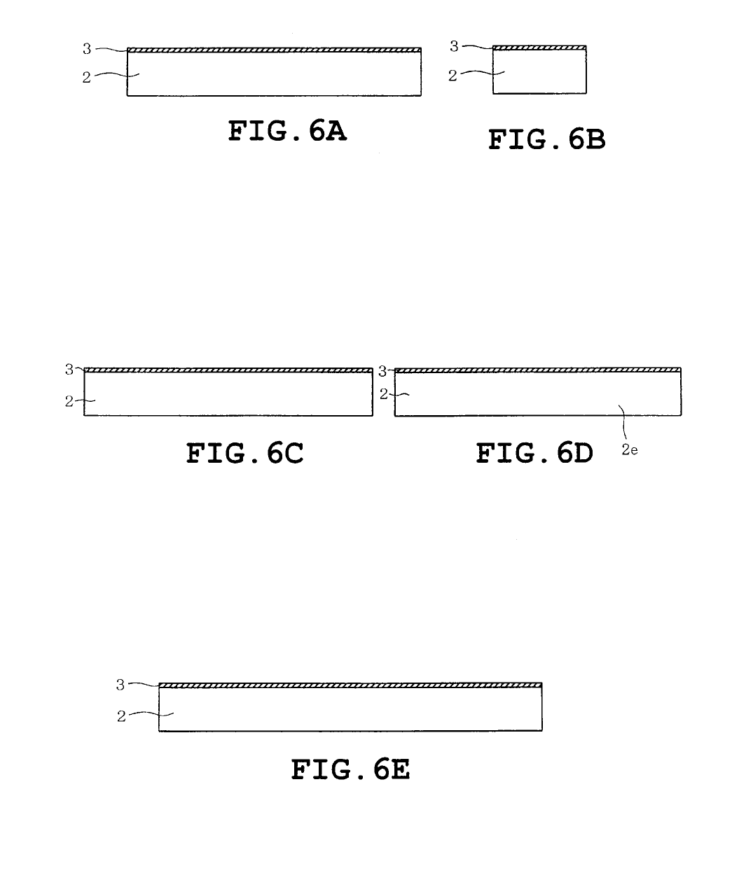

As shown in FIGS. 6A to 6E, gate insulating film 3 is formed above silicon substrate 2. Silicon substrate 2 comprises a p type silicon substrate. Gate insulating film 3 may be formed by thermal oxidation using dry O₂.

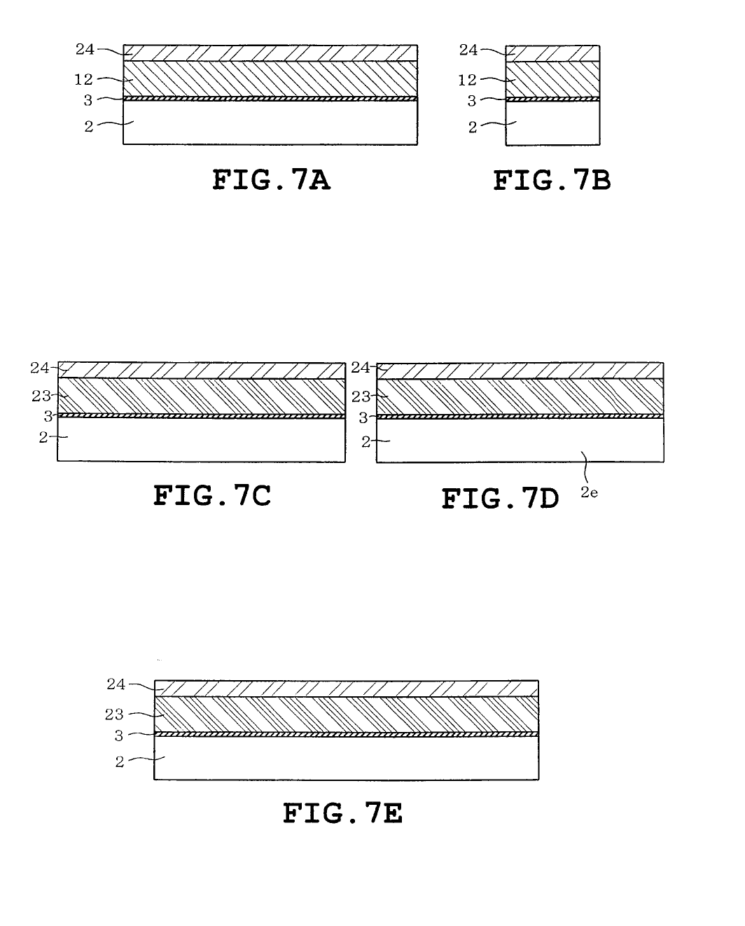

Referring now to FIGS. 7A to 7E, polycrystalline silicon film, undoped with impurities, is formed above gate insulating film 3 by CVD (Chemical Vapor Deposition). Then, a resist mask is formed by photolithography which is used as a mask in introducing impurities into the polycrystalline silicon film by ion implantation to obtain p-type first polycrystalline silicon film 12 and n-type fourth polycrystalline silicon film 23. P-type first polycrystalline silicon film 12 is formed in memory-cell region M indicated in FIGS. 7A and 7B, whereas n-type fourth polycrystalline silicon film 23 is formed in the peripheral circuit region indicated in FIGS. 7C, 7D, and 7E. Mask silicon nitride film 24 is formed above first polycrystalline silicon film 12 and fourth polycrystalline silicon film 23. In the above described example, first polycrystalline silicon film 12 and fourth polycrystalline silicon film 23 were formed by forming a polycrystalline silicon film undoped with impurities and thereafter doping impurities by ion implantation wherever required using mask formed by photolithography to obtain both n-type and p-type polycrystalline silicon. An alternative approach discussed below may be employed as well. Impurities such as boron is introduced during the formation of polycrystalline by CVD to obtain a p-type polycrystalline silicon whereafter p-type polycrystalline silicon located in the non-memory cell region is removed. Then, n-type polycrystalline silicon is formed in a similar manner whereafter n-type polycrystalline silicon in the memory-cell region is removed. This alternative approach also achieves the structure illustrated in FIGS. 7A to 7E.

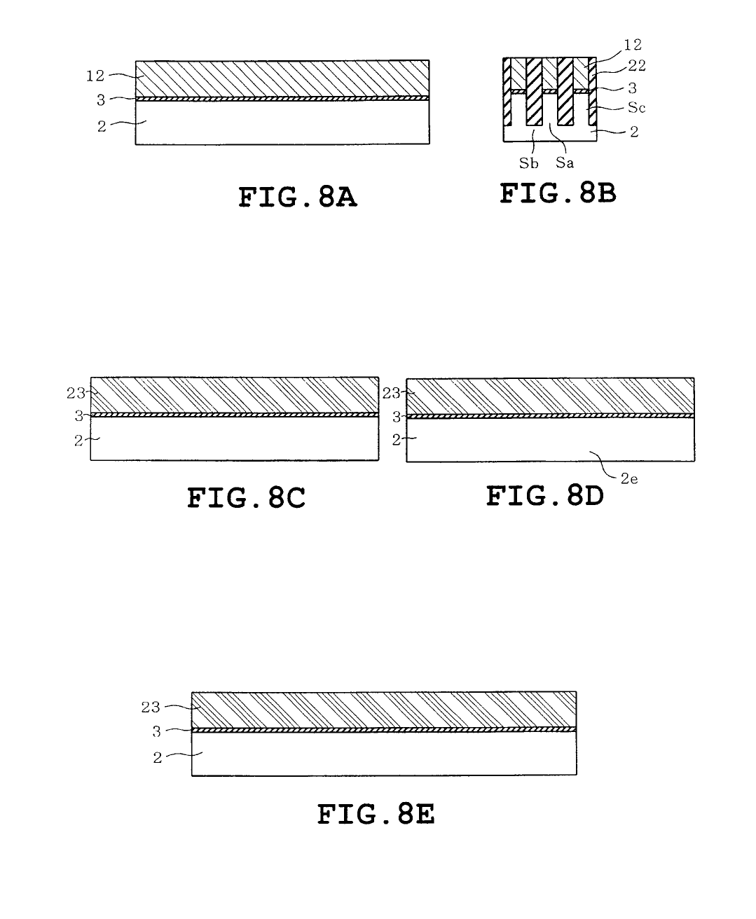

Next, as shown in FIGS. 8A to 8E, a resist mask is formed by photolithography which is used to form element region Sa and element isolation region Sb. Using the resist mask, mask silicon nitride 24, first polycrystalline silicon film 12, fourth polycrystalline silicon film 23, gate insulating film 3, and silicon substrate 2 are anisotropically dry etched in the listed sequence. This patterns the first polycrystalline silicon film 12 and fourth polycrystalline silicon film 23 and further forms element isolation trenches Sc.

Then, element isolation trench Sc is overfilled with element isolation insulating film 22, whereafter the overflow of element isolation insulating film 22 is polished away by CMP (Chemical Mechanical Polishing) until a thin layer remains above mask silicon nitride film 24. Element isolation insulating film 22 may comprise a coating type silicon oxide film. Mask silicon nitride film 24 is used as a stopper film in the CMP of element isolation insulating film 22. After the CMP, mask silicon nitride film 24 is removed using hot phosphoric acid. The above process flow delineates element region Sa and element isolation region Sb. The formation of element isolation region Sb in the peripheral circuit region also takes place simultaneously.

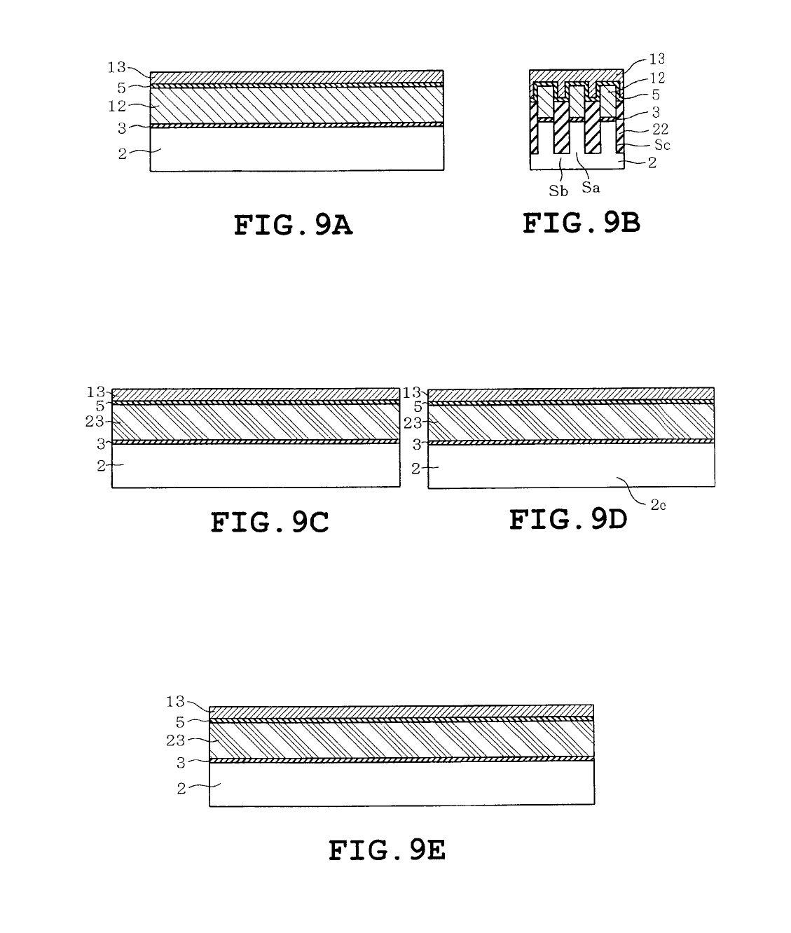

As shown in FIGS. 9A to 9E, element isolation insulating film 22 in element isolation trench Sc located in memory-cell region M is etched back so that the upper surface of element isolation insulating film 22 is lowered to approximately mid height of first polycrystalline silicon film 12. Thereafter, interelectrode insulating film 5 and second polycrystalline silicon film 13 are blanketed in the listed sequence. Interelectrode insulating film 5 may comprise an ONO film. Second polycrystalline silicon film 13 may be formed by CVD. Then, impurity such as boron is introduced into second polycrystalline silicon film 13 by ion implantation to obtain a p-type polycrystalline silicon.

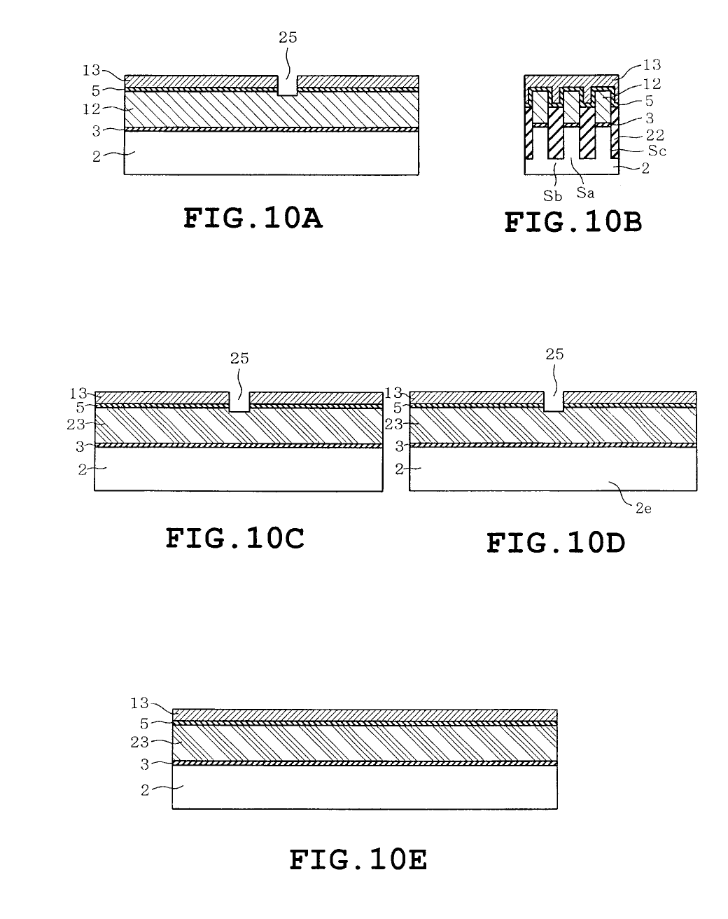

As shown in FIGS. 10A to 10E, opening 25 is formed by selectively removing a portion of second polycrystalline silicon film 13 and interelectrode insulating film 5 by photolithography in portions in which gate electrodes SG of select transistors STS and STD and gate electrode PG of peripheral circuit transistors PT are to be formed as shown in FIGS. 10A, 10C, and 10D.

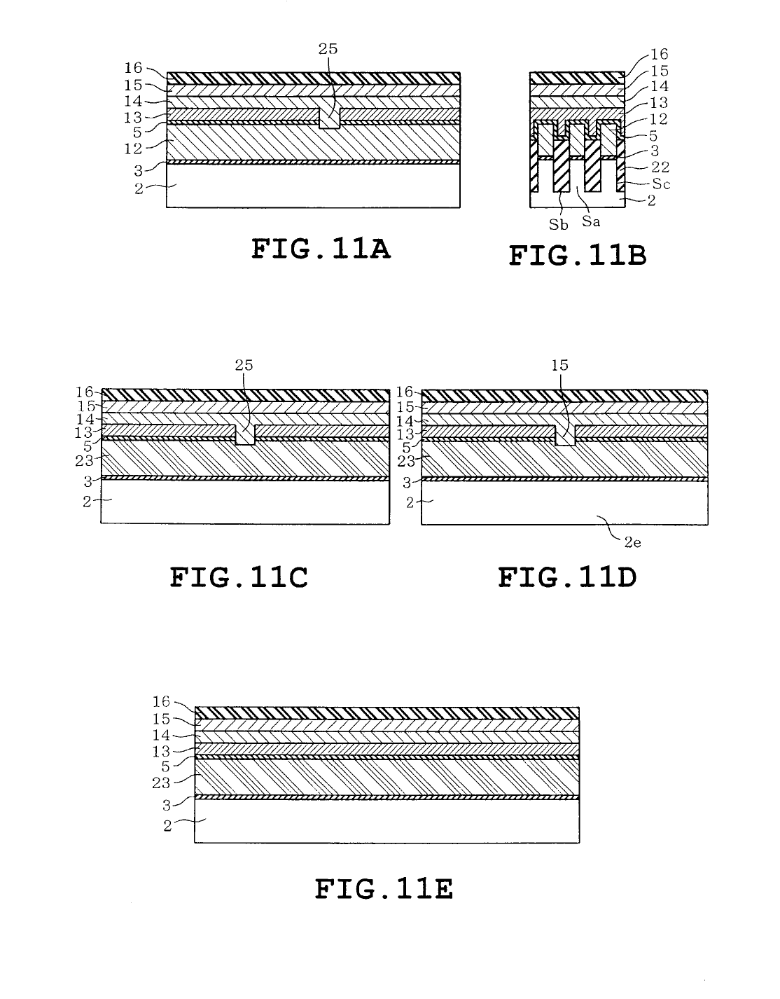

Referring to FIGS. 11A to 11E, third polycrystalline silicon film 14 undoped with impurities is blanked by CVD which is thereafter doped with boron by ion implantation to obtain a p-type polycrystalline silicon. As a result, connection is established between third polycrystalline silicon film 14 and first polycrystalline silicon film 12 through opening 25 to render first polycrystalline silicon film 12 to be electrically conductive with second polycrystalline silicon film 13 and third polycrystalline silicon film 14. Then, metal film 15 and silicon nitride film 16 are formed in the listed sequence. One example of metal film 15 is a sputtered tungsten (W) film. Silicon nitride film 16 may be formed by CVD. A barrier film comprising materials such as tungsten nitride (WN) may be formed between third polycrystalline silicon film 14 and metal film 15.

In the above described example, second polycrystalline silicon film 13 and third polycrystalline silicon film 14 were formed by forming a polycrystalline silicon film undoped with impurities and thereafter doping impurities by ion implantation. An alternative approach discussed below may be employed as well Impurity such as boron is introduced during the formation of polycrystalline silicon by CVD to obtain a polycrystalline silicon doped with impurities.

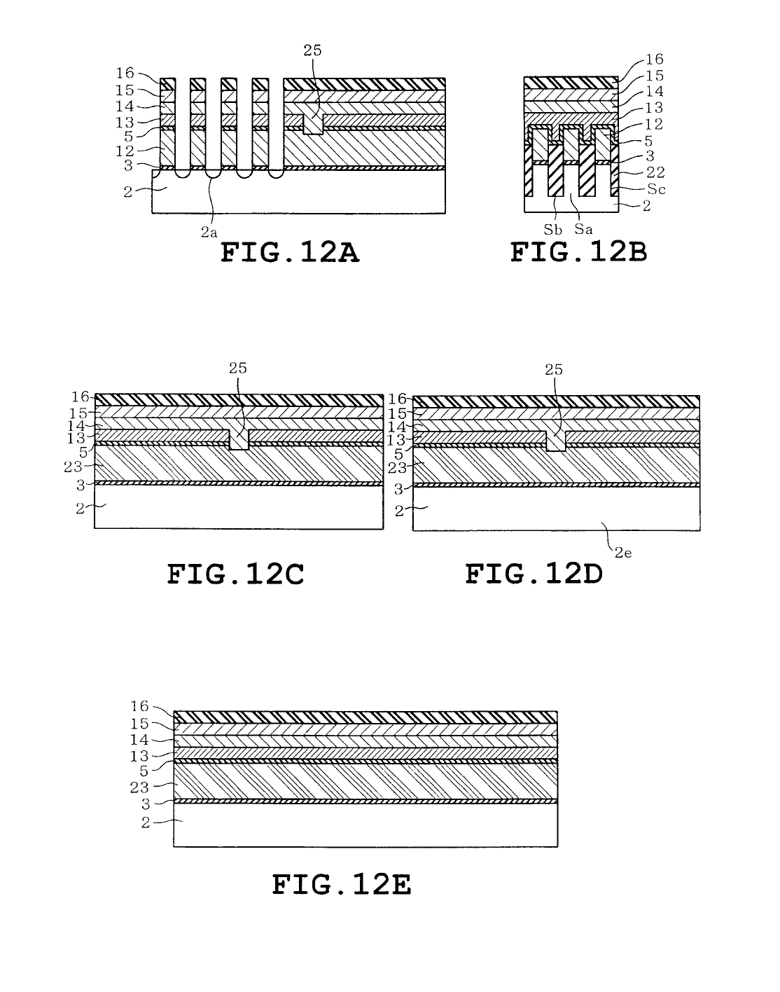

Then, as shown in FIGS. 12A to 12E, gate electrode MG of memory-cell transistor MT is patterned using photolithography. Gate electrode MG is patterned by anisotropic dry etching using a resist mask formed by photolithography as a mask. Anisotropic etching progresses through silicon nitride film 16, metal film 15, third polycrystalline silicon film 14, second polycrystalline silicon film 13, interelectrode insulating film 5, and first polycrystalline silicon film 12. The above describe process flow also patterns the sidewall of gate electrode SG of select transistor STD adjacent to the memory-cell transistor MT. Then, impurities such as phosphorous is introduced into silicon substrate 2 located between gate electrode MG, and between gate electrodes MG and SG by ion implantation. The above described process flow forms source/drain region 2a of memory-cell transistor MT.

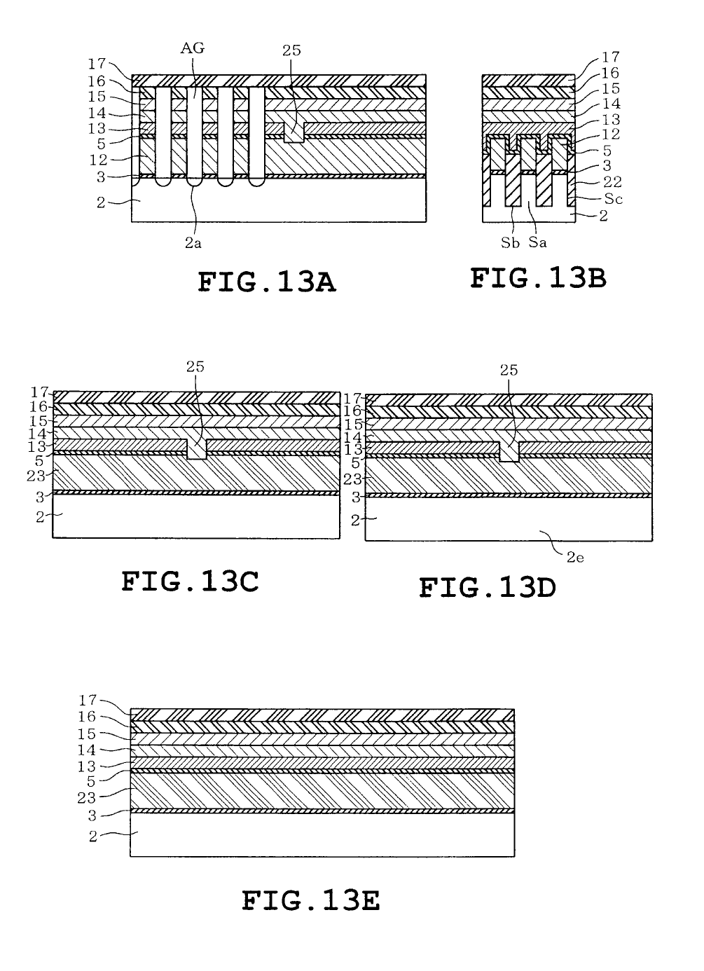

Referring now to FIGS. 13A to 13E, first insulating film 17 is blanketed. First insulating film 17 may comprise a silicon oxide film formed by CVD. First insulating film 17 is formed under conditions providing poor step coverage. Because the gaps between gate electrodes MG and between gate electrode SG and gate electrode MG are narrow, first insulating film 17 is formed so as to extend across the tops of gate electrodes MG and across gate electrode SG and gate electrode MG so as to provide a lid over the gaps between the foregoing electrodes without filling the gaps.

As a result, unfilled air gaps AG are formed between gate electrodes MG and between gate electrodes SG and the adjacent gate electrode MG. Air gaps AG reduces the capacitance between the wirings of gate electrodes MG. Gate insulating film 3 located between gate electrodes MG are removed prior to the formation of first insulating film 17.

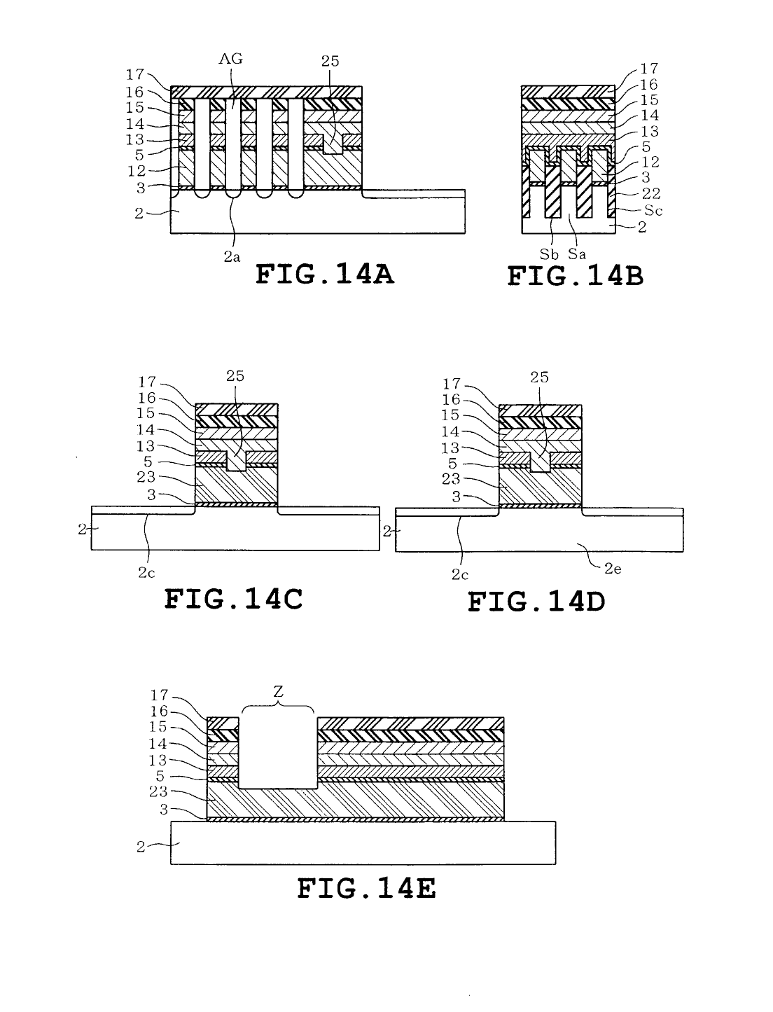

Referring now to FIGS. 14A to 14E, first interlayer insulating film 17, silicon nitride film 16, metal film 15, third polycrystalline silicon film 14, second polycrystalline silicon film 13, interelectrode insulating film 5, and fourth polycrystalline silicon film 23 are etched in the listed sequence using photolithography and anisotropic dry etching. This patterns the stack of films into the shapes of gate electrode SG of select transistor STD, gate electrode PG of peripheral circuit transistor PT, and capacitive element C. Then, using photolithography and ion implantation, impurities such as phosphorous is lightly doped into the source/drain region of select transistor STD located in the opposite side of memory-cell region M, and into the source/drain region of n-channel type transistor Trn of peripheral circuit transistor PT. Similarly, impurity such as boron is lightly doped into the source/drain region of p-channel type transistor Trp. The above described process flow forms lightly-doped source/drain regions 2c of transistors employing an LDD structure.

Using photolithography, first insulating film 17, silicon nitride film 16, metal film 15, third polycrystalline silicon film 14, second polycrystalline silicon film 13, and interelectrode insulating film 5 located in region Z of capacitive element C are removed. As a result, the surface of fourth polycrystalline silicon film 23 in region Z of second conductor Cb is exposed.

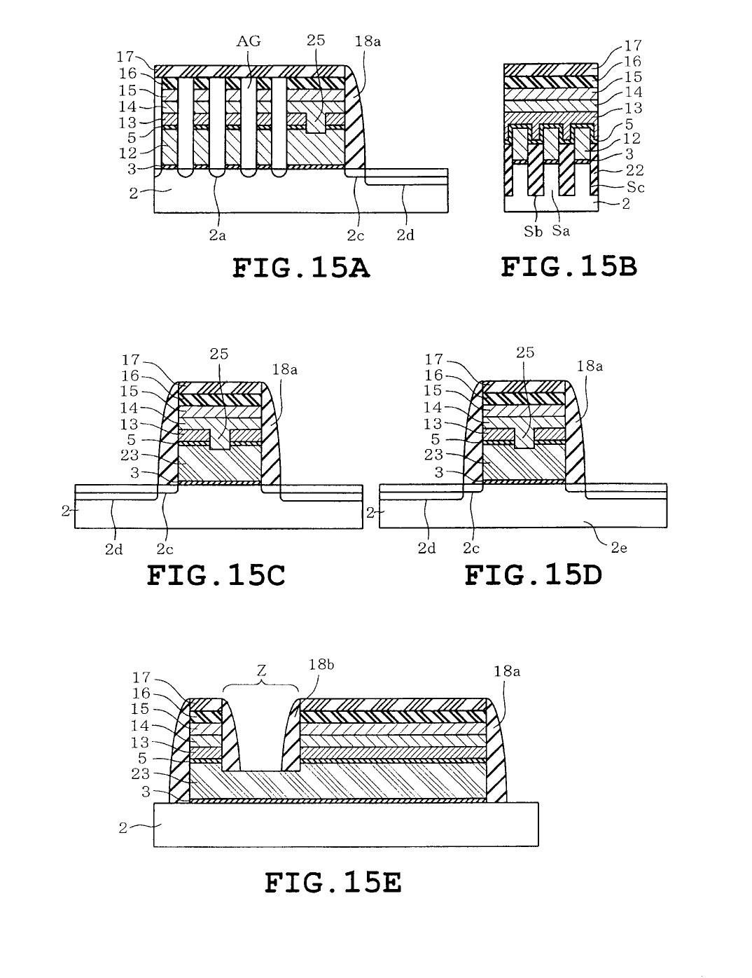

Referring now to FIGS. 15A to 15E, an insulating film is blanketed by CVD under conditions providing good step coverage which is followed by an anisotropic etch back to form spacers 18a along the sidewalls of gate electrode SG, PG and the electrode of capacitive element C so as to extend from the height of the upper surface of each electrode to the height of the upper surface of silicon substrate 2. At the same time, spacer 18b is formed along the sidewalls of region Z of capacitive element C so as to extend from the height of the upper surface of second conductor Cb to the height of the upper surface of fourth polycrystalline silicon film 23. The insulating film forming spacers 18a and 18b may comprise a silicon oxide film. Then, using ion implantation, impurities such as phosphorous or arsenic may be heavily doped into the source/drain region of select transistor STD located in the opposite side of memory-cell region M and into the source/drain region of n-channel type transistor Trn of a peripheral circuit transistor PT which is not covered by spacer 18a. Similarly, impurities such as boron may be heavily doped the into source/drain region of p-channel type transistor Trp which is not covered by spacer 18a. The above described process flow forms heavily-doped source/drain regions 2d of transistors employing an LDD structure.

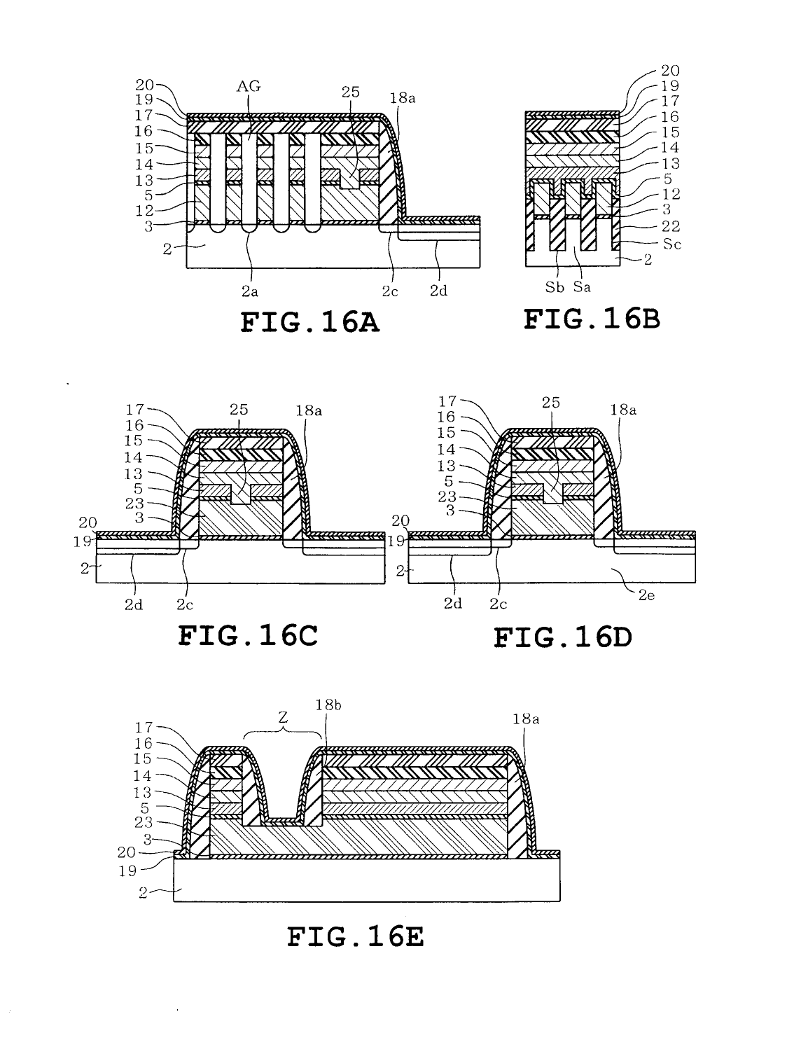

Referring now to FIGS. 16A to 16E, second insulating film 19 and third insulating film 20 are formed in the listed sequence so as to cover the upper surface of silicon substrate 2 which was subjected to the foregoing process flow. Second insulating film 19 may comprise a silicon oxide film formed by CVD. Third insulating film 20 may comprise a silicon nitride film 20 formed by CVD.

Referring to FIGS. 5A to 5E, interlayer insulating film 7 is formed above the upper surface of silicon substrate 2 which was subjected to the foregoing process flow. Then, contact plugs 21a, 21b, and 21c are formed that reach the source/drain region of the peripheral circuit transistor PT, the gate electrode PG of the peripheral circuit transistor PT and the second conductor Cb of capacitive element C, and first conductor Ca of region Z, respectively.

The formation of contact plugs 21a, 21b, and 21c are carried out as follows. Using a resist mask formed by photolithography as an etch mask, interlayer insulating film 7, third insulating film 20, second insulating film 19, first insulating film 17, and silicon nitride film 16 are etched in the listed sequence by anisotropic dry etching. The etching forms a contact hole that extends from the upper surface of interlayer insulating film 7 to silicon substrate 2, metal film 15, and fourth polycrystalline silicon film 23, respectively. Then, the contact holes are filled with a conductive material. The conductive material may comprise tungsten (w) which may be filled after lining the contact holes with a barrier film comprising titanium nitride (TiN). The above described process flow forms contact plugs 21a, 21b, and 21c.

The above described manufacturing process flow forms the NAND flash memory device of the first embodiment.

In the above described NAND flash memory device, gate electrode MG of memory-cell transistor MT employs floating gate electrode 4 comprising a p-type first polycrystalline silicon film 12. Thus, advantageously, electrons accumulated in floating gate electrode 4 are not easily released as compared to a floating gate electrode comprising an n-type polycrystalline silicon film. This improves the data retention properties of the NAND flash memory device.

When a p-type polycrystalline silicon is used in the floating gate electrode in order to improve the properties of memory-cell transistor MT, it may not be able to control the properties of a peripheral circuit transistor PT, for example the threshold voltage property or punch through property. In the first embodiment, however, the floating gate electrode in the memory cell region and the corresponding structure (i.e., the lower electrode) in the peripheral circuit region are formed in a different manner. It is possible to control the properties of the memory-cell transistor MT and peripheral circuit transistor PT easily.

Conventionally, the electrodes of peripheral circuit transistors PT were often formed of the same film material as gate electrode MG of memory-cell transistor MT. In such case, the lower electrode layer of peripheral circuit transistor PT becomes a p-type polycrystalline silicon. Further, an n-channel peripheral circuit transistor Trn which comprises an n-gate n channel type transistor in the first embodiment becomes a p gate-n channel type transistor. This causes varying of the work function of the gate electrode opposing silicon substrate 2 serving as the channel of the n-channel type transistor Trn. Further, because silicon substrate 2 is a p type, the n-channel type transistor Trn is altered from a surface-channel type to a buried-channel type.

In a p-channel type transistor Trp on the other hand, an n-gate p channel type transistor in the first embodiment becomes a p gate p channel type transistor. This causes varying the work function of the gate electrode opposing silicon substrate 2 serving as the channel of the p-channel type transistor Trp. Further, because silicon substrate 2 is located in an n-type n well, p-channel type transistor Trp is altered from a buried-channel type to a surface-channel type.

Thus, the attempt to improve the performance of memory-cell transistor MT causes a significant variation in the properties of both the n-channel type transistor Trn and in p-channel type transistor Trp. Under such circumstances, some level of threshold voltage adjustment may be possible by re-designing the peripheral circuit of the nonvolatile semiconductor storage device. This may be cumbersome and may prolong the duration of the design phase. On the other hand, by not forming a film corresponding to first polycrystalline silicon film 12 of the memory-cell region in the peripheral circuit region and instead forming an n-type polycrystalline silicon (fourth polycrystalline silicon film 23), re-designing of the peripheral circuit region can be eliminated to prevent cost increase.

Further, the use of first polycrystalline silicon film 12 employed in gate electrode MG of memory-cell transistor MT in polycrystalline silicon of first conductor Ca of capacitive element C creates a depleted layer in first conductor Ca when capacitive element C is in operation. This brings down the capacitance of capacitive element C. The formation of such depleted layer can be prevented by employing the configuration of the first embodiment. As a result, capacitive element C with large capacitance per unit area can be obtained which in turn contributes to smaller chip area and thus, cost reduction of the nonvolatile semiconductor device.

### Second Embodiment

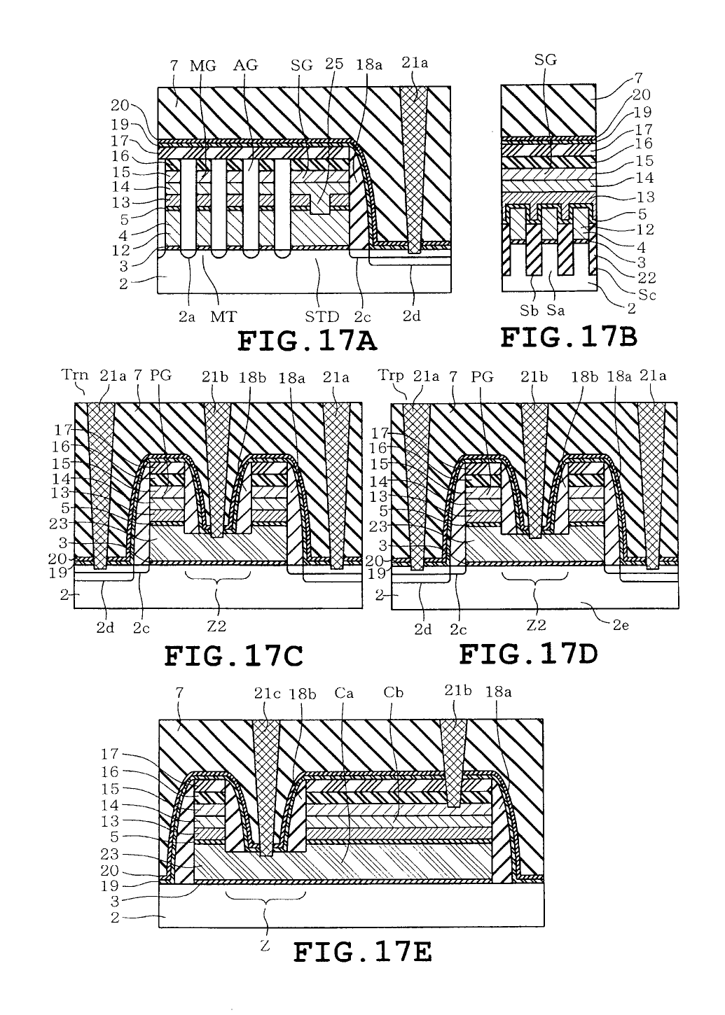

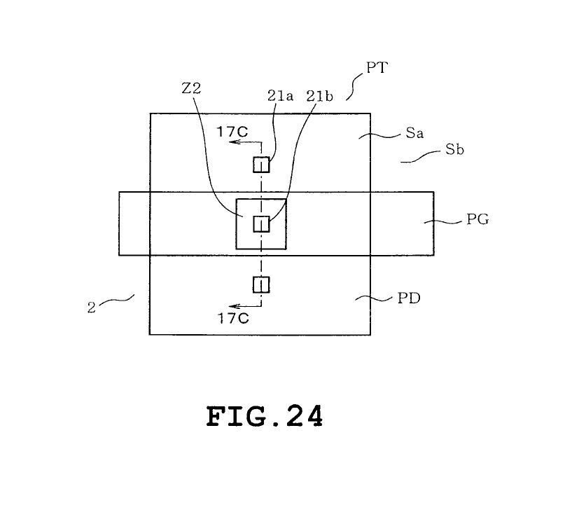

Next, a description will be given on a second embodiment with reference to FIGS. 17A to 21E, and FIG. 24. FIG. 24 is one example of a planar layout of a peripheral circuit transistor PT of the second embodiment. FIGS. 17A to 17E are schematic examples of structures and manufacturing process flows of a NAND flash memory device of the second embodiment. FIGS. 17C and 17D are examples of cross sections taken along line 17C-17C of FIG. 24. The planar layouts of the structures are identical to those illustrated in FIGS. 2 and 4A and 4B with the exception of FIG. 24 and thus will not be described.

The second embodiment differs from the first embodiment in that the contact to gate electrode PG of peripheral circuit transistor PT is established by direct connection with fourth polycrystalline silicon film 23 of gate electrode PG. Thus, as compared to the structure of the first embodiment in which the contact to gate electrode PG is established through metal film 15, interface resistance between metal film 15 and third polycrystalline silicon film 14 can be eliminated.

Further, the tunnel-diode formed of the P-N junction between third polycrystalline silicon film 14 and fourth polycrystalline silicon film 23 produces a slight negative resistance when forward bias is applied. However, operational delays originating from the negative resistance can be avoided by establishing the contact to gate electrode PG through the connection to fourth polycrystalline silicon film 23.

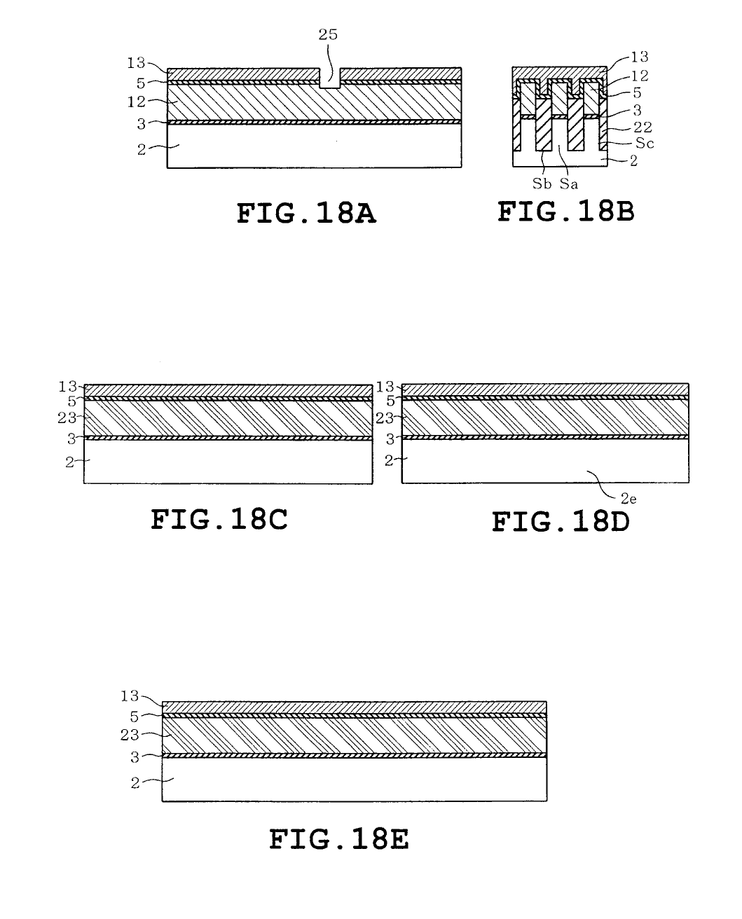

The manufacturing process flow of the nonvolatile semiconductor storage device of the second embodiment will be described with reference to FIGS. 17A to 21E. First, the process flows shown in FIGS. 6A to 9E of the first embodiment are carried out. Then, as shown in FIGS. 18A to 18E, opening 25 is formed by selectively removing a portion of second polycrystalline silicon film 13 and interelectrode insulating film 5 by photolithography in portions in which gate electrodes SG of select transistors STD are to be formed. The difference from the first embodiment is that opening 25 is not formed in gate electrode PG of peripheral circuit transistors PT.

Process flows indicated in FIGS. 11A to 13E of the first embodiment are carried out.

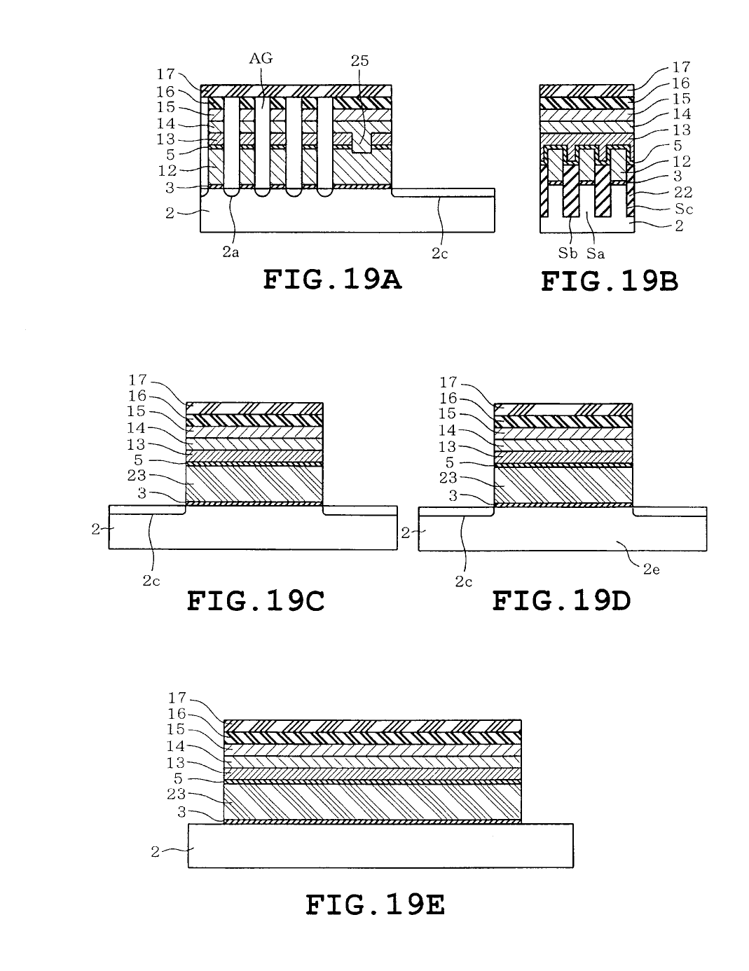

As shown in FIGS. 19A to 19E, first interlayer insulating film 17, silicon nitride film 16, metal film 15, third polycrystalline silicon film 14, second polycrystalline silicon film 13, interelectrode insulating film 5, and first polycrystalline silicon film 12 are etched in the listed sequence using photolithography and anisotropic dry etching. This patterns the stack of films into the shapes of gate electrode SG of select transistor STD, gate electrode PG of peripheral circuit transistor PT, and capacitive element C.

Using ion implantation, impurities such as phosphorous is lightly doped into the source/drain region of select transistor STD located in the opposite side of memory-cell region M, and into the source/drain region of n-channel type transistor Trn of peripheral circuit transistor PT. Similarly, impurity such as boron is lightly doped into the source/drain region of p-channel type transistor Trp. The above described process flow forms lightly-doped source/drain regions 2c of transistors employing an LDD structure.

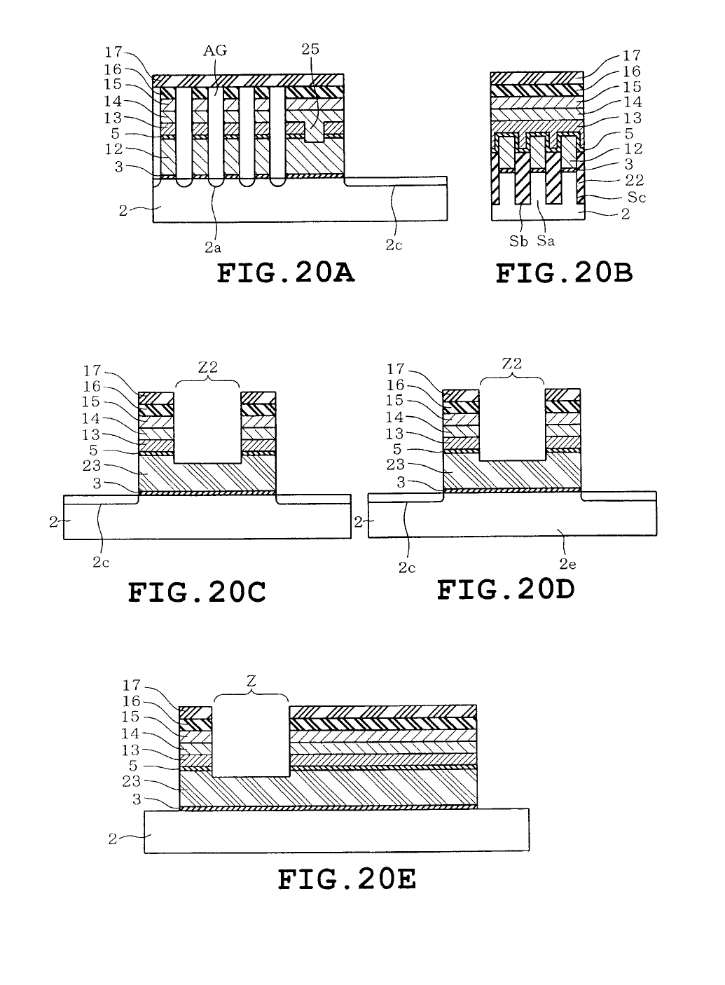

As shown in FIGS. 20A to 20E, first insulating film 17, silicon nitride film 16, metal film 15, third polycrystalline silicon film 14, second polycrystalline silicon film 13, and interelectrode insulating film 5 located in region Z of capacitive element C and region Z2 of gate electrode PG of peripheral circuit transistor PT are removed using photolithography. Region Z2 is a region corresponding to region Z which is formed in gate electrode PG of peripheral circuit transistor PT and where the upper electrode layer corresponding to second conductor Cb is removed as shown in FIGS. 20C and 20D. As a result, the surfaces of fourth polycrystalline silicon film 23 in region Z and region Z2 are exposed.

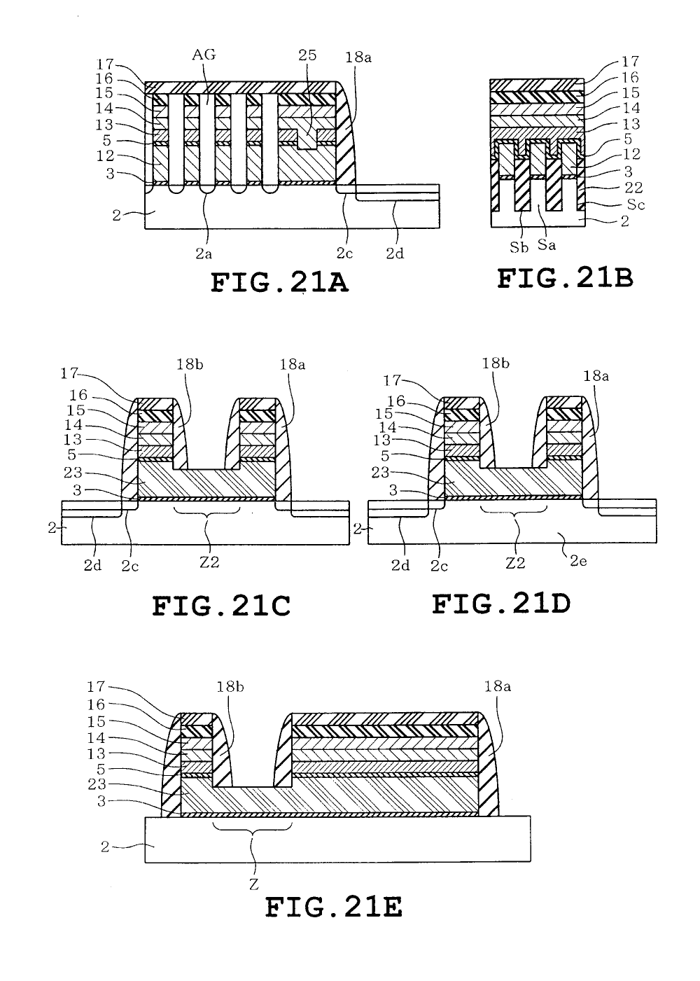

As the result of process flow shown in FIGS. 15A to 15E of the first embodiment, spacers 18a shown in FIGS. 21A to 21E are formed. Spacer 18a is formed along the sidewalls of gate electrode SG, PG and the electrode of capacitive element C so as to extend from the height of the upper surface of each electrode to the height of the upper surface of silicon substrate 2. At the same time, spacer 18b is formed along the sidewalls of second conductor Cb located in region Z of capacitive element C and along the sidewalls of upper electrode layer located in region Z2 of gate electrode PG so as to extend from the height of the upper surface of each electrode to the height of the upper surface of fourth polycrystalline silicon film 23.

Referring to FIGS. 17A to 17E, second insulating film 19 and third insulating film 20 are formed in the listed sequence so as to cover the surface of silicon substrate 2 followed by formation of interlayer insulating film 7. Then, using photolithography, contact plugs 21a, 21b, and 21c are formed. Contact plug 21a extends to the source/drain regions of select transistor STD and peripheral circuit transistor PT. Contact plug 21b extends to second conductor Cb of capacitive element C. Contact plug 21c extends to first conductor Ca located in region Z and the lower electrode layer (fourth polycrystalline silicon film 23) of gate electrode PG located in region Z2.

The NAND flash memory device of the second embodiment is manufactured by the above described manufacturing process flow.

In the above described example, the contact to gate electrode PG of n-channel type transistors Trn and p-channel type transistor Trp were established by connection to fourth polycrystalline silicon film 23. Alternatively, the following configuration may be employed. For example, the contact to gate electrode PG of n-channel type transistors Trn may be established by connection to metal film 15 as shown in FIG. 5C, whereas the contact to gate electrode PG of p-channel type transistor Trp may be established by direct connection to fourth polycrystalline silicon film 23 as shown in FIG. 17C.

### Third Embodiment

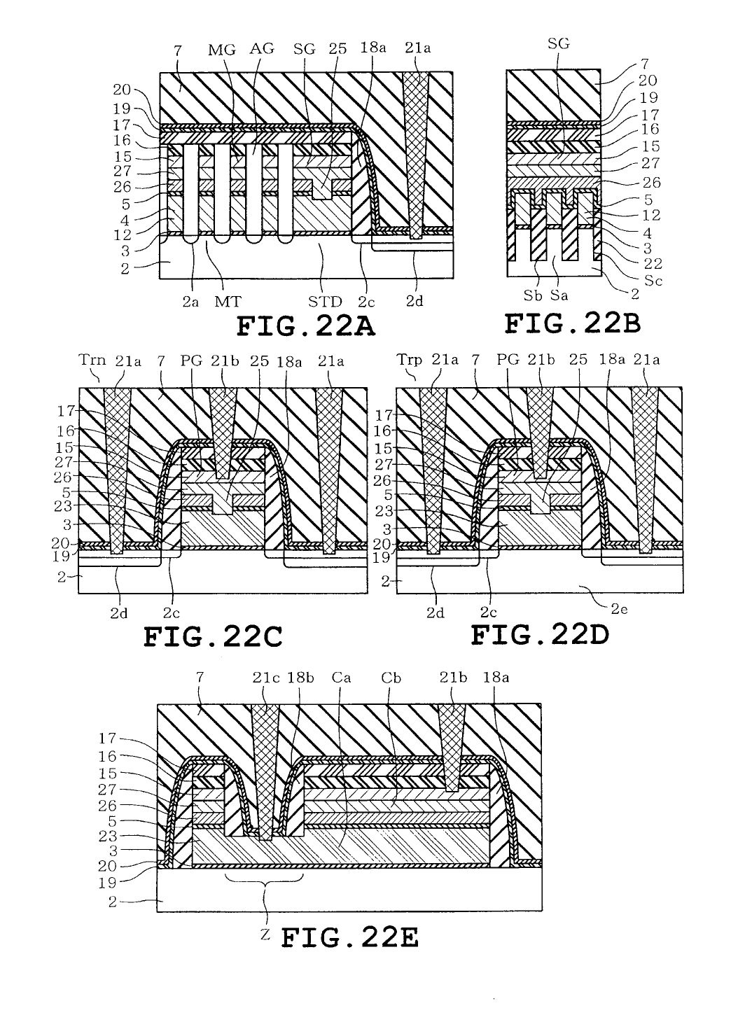

Next, a description will be given on a third embodiment with reference to FIGS. 22A to 22E. The third embodiment differs from the first embodiment in that the second polycrystalline silicon film 13 and third polycrystalline silicon film 14 are replaced by n-type fifth polycrystalline silicon film 26 and sixth polycrystalline silicon film 27. The rest of the structure remains the same from the first embodiment. Thus, in gate electrode MG of the memory-cell transistor MT, first polycrystalline silicon film 12 constituting floating gate electrode 4 becomes a p type and fifth polycrystalline silicon film 26 and sixth polycrystalline silicon film 27 constituting the control gate electrode becomes an n type. In gate electrode SG of select transistor STD, on the other hand, the p type first polycrystalline silicon film 12 and the n type fifth polycrystalline silicon film 26 and sixth polycrystalline silicon film 27 are connected through opening 25. In the peripheral circuit transistor PT, on the other hand, the n type fourth polycrystalline silicon film 23 and the n type fifth polycrystalline silicon film 26 and sixth polycrystalline silicon film 27 are connected through opening 25.

In gate electrode SG of select transistor STD, a P-N junction is formed between the p-type first polycrystalline silicon film 12 and the n-type sixth polycrystalline silicon film 27 in opening 25. However, as was the case in peripheral circuit transistor PT in the first embodiment, first polycrystalline silicon film 12 and sixth polycrystalline silicon film 27 are heavily doped with impurities of approximately 1×10²⁰ to 1×10²¹ atms/cm³, for example. Thus, the P-N junction formed at opening 25 behaves like a tunnel diode formed in heavily doped n-type/p-type regions. Thus, carrier transport occurs by tunneling even when a reverse bias voltage is applied to the P-N junction, resulting in a conductive state in both forward and reverse voltage control.

In peripheral circuit transistor PT on the other hand, fourth polycrystalline silicon film 23 is used which differs in conductive type from first polycrystalline silicon film 12 serving as floating gate electrode 4 of memory-cell transistor MT. Thus, the properties of memory-cell transistor MT and peripheral circuit transistor PT can be controlled separately. Further, P-N junction is not produced in opening 25 and thus, conduction need not be established through the tunnel diode formed by the P-N junction as was the case in the first embodiment, to thereby increase the operational speed of the transistors.

In the third embodiment, the structure of contact to gate electrode SG of select transistor STD may be established by direct connection to first polycrystalline silicon film 12 as was the case in gate electrode PG of peripheral circuit transistor PT of the second embodiment. In such case, interface resistance between metal film 15 and sixth polycrystalline silicon film 27 can be eliminated in gate electrode SG of select transistor STD. Further, a slight negative resistance is produced by the tunnel diode formed at the P-N junction in opening 25 when forward bias is applied. Operational delay originating from the negative resistance can be avoided by establishing the contact to gate electrode PG through connection to first polycrystalline silicon film 12. Thus, operational speed of select transistor STD can be increased.

The manufacturing process flow for obtaining the structure of the third embodiment only requires the formation of second polycrystalline silicon film 13 and third polycrystalline silicon film 14 in the process flows indicated in FIGS. 9A to 11E to be replaced by formation of n-type fifth polycrystalline silicon film 26 and sixth polycrystalline silicon film 27. In such case, fifth polycrystalline silicon film 26 and sixth polycrystalline silicon film 27 may be doped with impurities such as phosphorous or arsenic.

### Other Embodiments

The embodiments described above may be modified as follows.

One example of capacitive element C was described through an equivalent circuit indicated in FIG. 4C, however, equivalent circuits of different circuit configurations may be applied. For instance, first capacitive element C1 and second capacitive element C2 may be connected in parallel.

The above described embodiments were directed to NAND flash memory device, however, other embodiments may be directed to other nonvolatile semiconductor storage devices such as NOR flash memory and EERROM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a p-type semiconductor substrate;
a gate insulating film formed above the semiconductor substrate;
a memory-cell transistor and a peripheral circuit transistor formed above the gate insulating film;
wherein the memory-cell transistor includes a first gate electrode including a stack of a floating gate electrode comprising a p-type first polycrystalline silicon film, an interelectrode insulating film, and a control gate electrode comprising a p-type second polycrystalline silicon film, and
wherein the peripheral circuit transistor includes a second gate electrode including a stack of a lower electrode comprising an n-type third polycrystalline silicon film; a first insulating film having an opening and being located above the lower electrode, an upper electrode comprising the same material as the second polycrystalline silicon film and contacting the third polycrystalline silicon film through the opening of the first insulating film.

2. The device according to claim 1, wherein the peripheral circuit transistor further includes a first contact that contacts the lower electrode.

3. The device according to claim 1, wherein the first polycrystalline silicon film of the floating gate electrode is doped with boron impurity, the second polycrystalline silicon film of the control gate electrode is doped with boron impurity, the third polycrystalline silicon film of the lower electrode is doped with phosphorous or arsenic impurity, and the second polycrystalline silicon film of the upper electrode is doped with boron impurity.

4. The device according to claim 1, wherein the memory-cell transistor is an n-channel type and buried-channel type transistor, the peripheral circuit transistor is an n-channel type and surface-channel type transistor or a p-channel type and buried-channel type transistor.

5. The device according to claim 1, wherein a P-N junction is formed in a portion of contact between the third polycrystalline silicon film of the lower electrode and the second polycrystalline silicon film of the upper electrode.

6. The device according to claim 1, wherein the first polycrystalline silicon film of the floating gate electrode and the third polycrystalline silicon film of the lower electrode are formed in the same step, and the second polycrystalline silicon film of the control gate electrode and the second polycrystalline silicon film of the upper electrode are formed in the same step.

7. The device according to claim 1, further comprising a capacitive element, wherein the capacitive element includes a first capacitance including the semiconductor substrate, the gate insulating film, and a first conductor having the third polycrystalline silicon film and being formed above the gate insulating film; a second capacitance including the first conductor, a second insulating film having the same material as the interelectrode insulating film, and a second conductor being formed above the second insulating film and having the second polycrystalline silicon film; and a second contact that contacts the first conductor.

8. The device according to claim 7, wherein the peripheral circuit transistor further includes a first contact that contacts the lower electrode.

9. A nonvolatile semiconductor storage device comprising:
a p-type semiconductor substrate;
a gate insulating film formed above the semiconductor substrate; and
a memory-cell transistor and a capacitive element formed above the gate insulating film;
wherein the memory-cell transistor includes a first gate electrode including a stack of a floating gate electrode having a p-type first polycrystalline silicon film, an interelectrode insulating film, and a control gate electrode having a p-type second polycrystalline silicon film, and
wherein the capacitive element includes a first capacitance including the semiconductor substrate, the gate insulating film, and a first conductor having an n-type third polycrystalline silicon film provided above the gate insulating film; a second capacitance including the first conductor, a first insulating film having the same material as the interelectrode insulating film, and a second conductor being provided above the first insulating film and having the second polycrystalline silicon film; and a contact that contacts the first conductor.

10. The device according to claim 9, wherein the contact extends through a region where the second conductor is removed and contacts the third polycrystalline silicon film of the first conductor.

11. The device according to claim 9, wherein the first polycrystalline silicon film of the floating gate electrode is doped with boron impurity, the second polycrystalline silicon film of the control gate electrode is doped with boron impurity, the third polycrystalline silicon film of the first conductor is doped with phosphorous or arsenic impurity, and the second polycrystalline silicon film of the second conductor is doped with boron impurity.

12. The device according to claim 9, wherein the memory-cell transistor is an n-channel type and buried-channel type transistor.

13. The device according to claim 9, wherein the capacitive element becomes accumulated in a first portion located at an interface of the gate insulating film and the semiconductor substrate, in a second portion located at an interface of the gate insulating film and the third polycrystalline silicon film of the first conductor, in a third portion located at an interface of the first insulating film and the third polycrystalline silicon film of the first conductor, and in a fourth portion located at an interface of the first insulating film and the second polycrystalline silicon film of the second conductor.

14. The device according to claim 9, wherein the first polycrystalline silicon film of the floating gate electrode and the third polycrystalline silicon film of the first conductor are formed in the same step, and the second polycrystalline silicon film of the control gate electrode and the second polycrystalline silicon film of the second conductor are formed in the same step.

15. A nonvolatile semiconductor storage device comprising:
a p-type semiconductor substrate;
a gate insulating film formed above the semiconductor substrate;
a memory-cell transistor and a peripheral circuit transistor formed above the gate insulating film;
wherein the memory-cell transistor includes a first gate electrode including a stack of a floating gate electrode having a p-type first polycrystalline silicon film, an interelectrode insulating film, and a control gate electrode having an n-type second polycrystalline silicon film, and
wherein the peripheral circuit transistor includes a second gate electrode including stack of a lower electrode having an n-type third polycrystalline silicon film, a first insulating film having an opening and comprising the same material as the interelectrode insulating film, an upper electrode having the second polycrystalline silicon film and being configured such that the second polycrystalline silicon film contacts the third polycrystalline silicon film through the opening of the first insulating film.

16. The device according to claim 15, wherein the first polycrystalline silicon film of the floating gate electrode is doped with boron impurity, the second polycrystalline silicon film of the control gate electrode is doped with phosphorous or arsenic impurity, and the third polycrystalline silicon film of the lower electrode and the second polycrystalline silicon film of the upper electrode are doped with phosphorous or arsenic impurity.

17. The device according to claim 16, wherein the memory-cell transistor is an n-channel type and buried channel type transistor, the peripheral circuit transistor is an n-channel type surface-channel type transistor or a p-channel type buried-channel type transistor.
